(19) United States
(12) Patent Application Publication
(10) Pub. No.: US 2026/0260927 A1
(43) Pub. Date: Sep. 3, 2026

(54) BATTERY FORMATION PROTOCOLS

(71) Applicant: Deakin University, Geelong (AU)

(72) Inventors: Maria Forsyth, Geelong (AU); Patrick Howlett, Geelong (AU); Jenny Sun, Geelong (AU)

(21) Appl. No.: 18/878,391

(22) PCT Filed: Jun. 30, 2023
(86) PCT No.: PCT/AU2023/050612

§ 371 Date: Dec. 23, 2024

(30) Foreign Application Priority Data
Jun. 30, 2022 (AU) 2022901847

(51) Int. Cl. H01M 10/054; H01M 4/02; H01M 4/04; H01M 4/587

(52) U.S. Cl. CPC H01M 10/054; H01M 4/0447; H01M 4/587; H01M 2004/021; H01M 2004/027

(57) ABSTRACT

The invention relates to improved formation protocols for NIB hard carbon anodes in super concentrated ionic liquid electrolytes. In contrast to established methods for carbonate-based solvents, a high current density 2 C formation protocol resulted in the highest specific capacity during subsequent cycling at ½ C current density, along with the lowest EIS resistance, compared with 1 C and 1/10 C formation protocols. Variable cycling conditions (e.g., ⅕ C for long term cycling) were not influenced by the high C-rate treatment, demonstrating the necessity of applying high rate formation protocols for conditioning in these electrolytes. XPS and NMR analysis revealed a thinner SEI layer was formed after high C-rate formation, which can facilitate the Na+ charge transfer and diffusion across the electrolyte/electrode boundary.

### FIELD OF THE INVENTION

The invention relates to rapid battery formation methods or protocols, particularly for sodium ion batteries involving hard carbon anodes.

### BACKGROUND

High energy density and long-life batteries are desirable, particularly where manufacturing cost is low. Rechargeable sodium ion battery cells are generally assembled in the discharged or “fresh” or “pristine” state meaning the cell is in a pre-cycling state. The fresh cell must be “formed” as a next step during battery manufacture. Battery cell formation is the process of performing a set of initial charge/discharge (polarisation cycles) operations on the fresh battery cell (typically ⅔ polarisation cycles) in the factory. During charging, the positive electrode active material (e.g., a sodium oxide) produces the transferrable sodium transport ions which diffuse to the negative electrode active material (e.g., carbon, graphite) where they are reduced and “absorbed” into the negative material, which prior to charging, is sodium ion free (pristine). On discharge, the reverse reactions occur, and the stored chemical energy is converted to electrical energy used to power an attached load. A charge step and subsequent discharge step is termed a “polarisation cycle”. During the first polarisation cycle, electrochemical electrolyte interphases build up at the electrodes, and mainly on the negative electrode in the form of a solid electrolyte interphase (SEI) which is a passivating layer formed at the anode surface for all sodium ion batteries using liquid electrolytes. SEI formation much depends on the cell's chemistry and electrolyte components as it forms from electrolyte component decomposition/reduction products which use up a portion of the electrolyte in the first few cycles. A useful formation protocol forms a good quality and robust SEI which is important for battery performance, resulting in improved cycling stability, higher capacity and/or higher Coulombic efficiency, all of which are evidence of reduced anode and electrolyte degradation. An ideal SEI provides fast transport for the transport ions across the interface, while being a good electronic insulator thereby protecting the electrolyte from further degradation which would otherwise quickly lead to capacity loss in the cell. The SEI should be stable under both cycling and ageing conditions. SEI formation results in an irreversible consumption of transport ions from the electrolyte during cycling causing a reduction in achievable capacity and an increase of the resistance and thus impedance within the cell. Conventionally, the best SEI layers are selectively permeable to the transport ion used, and are desired to be as thin as possible, typically only a few nanometres thick, as a thin SEI reduces resistance to ion transport supporting optimal battery performance. However, a SEI that is too thin cannot sufficiently protect the electrolyte from reduction at the anode. A good SEI is uniformly distributed across the surface of the anode completely preventing contact between the anode and electrolyte, should also be mechanically robust/strong, while being chemically inert to avoid undesirable side reactions.

Hard carbon (HC) are anode alternatives to graphite better suited to sodium cells but are known to have more much complex sodium ion absorption mechanisms and SEI formation processes. This is due to the reactive nature of HC due to their higher surface area and porous nature which leads to thick and uneven SEIs. Thicker SEIs will impede transport ion diffusion thereby reducing the battery performance, while an uneven SEI supports localised side reactions which degrade performance over time. Most HC/SEI studies involve conventional film forming electrolyte additives such as hexafluorophosphate or TFSI salts, various carbonates, fluorinated carbonates or other solvents, etc. Invariably, degradation products of these additives form part of the HC SEI on formation. However, breakdown products of state-of-the-art ester solvent based sodium ion battery electrolytes (e.g., propylene carbonate (PC) and ethylene carbonate (EC), ethyl methyl carbonate (EMC), dimethyl carbonate (DMC), and diethyl carbonate (DEC) etc.) result in an outermost SEI layer rich in organic species, making the SEI often unstable, with large charge transfer resistance and a high energy barrier for sodium ion transport. Some groups have included ionic liquid/carbonate electrolytes for NIBs, and attribute improved SEI layer to the ionic liquid electrolytes.

Cell chemistry dependent battery formation/conditioning protocols used in commercial battery manufacture usually up to a week to form the necessary robust and homogenous interphases. Typically, a few cycles of slow galvanostatic charge-discharge at a low current are carried out, with various resting periods at elevated temperatures. Conventionally slow formation is thought to produce the most uniform and stable SEI layer. Typically, a very small current density (e.g., 1/10C or 1/20C using equivalent low current density) is used for an extended period to maximise transport metal insertion and thus charge capacity into the negative electrode during formation charging to ensure a uniform and stable SEI layer has formed. Thus, formation times are very slow (e.g., ⅔ cycles @20 to 40 hours per polarisation cycle means 40 to 120 hours for formation alone, without resting etc.). Thus, battery production efficiency is low and there is high capital cost for conventional protocols. Current densities beyond a 1/1 C rate are believed to damage the electrodes through premature aging and so are considered detrimental to cell performance and so have been avoided during commercial formation. Further, fast formation could risk dendrite production during cycling (via electroplating) which will damage the cell and reduce performance under normal operation.

New formation protocols that balance electrochemical performance, manufacturing cost and time efficiency are desirable, particularly in the case of cells involving HC anodes. Sodium-ion batteries (NIBs) are regarded as the next generation LIB alternatives. The same slow and costly traditional formation protocols for LIBs are applied to NIBs. However, the SEI formed for NIBs are less stable than their LIB counterparts. Notable differences between Na⁺ and Li⁺, including increased Na⁺ size, and reactivity differences make uniform and stable SEI formation for NIBs more difficult. Finally, NIB SEI components exhibit increased solubility which is a problem for SEI stability. As such knowledge of SEI formation for LIBs is not directly transferrable to NIB formation and SEI formation in Na cells is empirically studied. Very little is known overall about desirable compositional characteristics of SEIs on HC for NIBs.

Rakov et al (Chem. Mater. 2022, 34; “Rakov 2022”) reported Li deposition/striping studies in a high viscosity super-concentrated electrolyte (1001L), where a single Li metal anode preconditioning step involving a high current density (≥10.0 mA cm⁻² to a 1.0 mAh cm⁻² depth of charge) was found to benefit the SEI composition compared to a low concentration Li salt-containing IL electrolyte due to a predominance of Liₓ(anion)_{y} (x>y) in the SEI composition. However, when a lower viscosity super-concentrated electrolyte containing 20 wt % of ether cosolvent was used (801L20DME), a more moderate preconditioning step current density (6.0 mA cm⁻²/1.0 mA cm⁻²) lead to an even better optimized Li deposition morphology and the best cycling performance even at an extreme current of 15.0 mA cm⁻²/1.0 mAh cm⁻². Due to the differing optimized current densities for the viscous electrolyte versus the more fluid electrolyte, Rakov 2022 suggested that individual, tailored pretreatment protocols should be applied dependent on the electrolyte composition, without, however, indicating how such protocols should be derived. Of note however is that Rakov 2022's focus is limited to SEI formation at a lithium metal anode in a symmetric cell after a single preconditioning step—there is nothing on SEI formation in HC anodes in NIBs. As explained, due to the unpredictable nature of the SEI formation on HC in NIBs, Rakov 2022 teaches nothing of value re SEI formation in NIB systems using hard carbon anodes.

Rakov 2020 (Nature Materials, 19, 2020, 1096-1101) applies different negative electrode polarisations as a preconditioning treatment before long electrochemical cycling in a sodium symmetric cell based on C₃mpyrFSI IL with 50 mol % NaFSI salt at 50° C. The different electrode polarisations were tested by applying three different current densities of 0.1, 1.0 and 5.0 mA cm⁻² for five brief cycles for a 0.1 mAh cm⁻² depth of charge per step. After preconditioning, each test cell was further cycled for a longer time at current densities of 0.1 and 1.0 mA cm⁻² for 20 cycles, and then at 5.0 mA cm⁻² for 10 cycles each. The cell preconditioned at 5.0 mA cm⁻² resulted in the largest initial polarization potential and shortest deposition time and for the subsequent cycling at both 0.1 mA cm⁻² and 1.0 mA cm⁻², showed the smallest overpotential among the three cells. The preconditioned cells at lower currents of 0.1 mA cm⁻² and 1.0 mA cm⁻² either failed due to short circuiting or exhibit unstable voltage profiles. There is nothing on SEI formation in HC anodes in NIBs. As explained, due to the unpredictable nature of the SEI formation on HC in NIBs, Rakov 2020 teachings involving Na metal symmetrical cells do not provide information on HC SEI formation in a Na-HC system in a NIB cell.

Recently, Kishore et al (Chem. Commun., 2020, 56, 12925-12928), acknowledges that formation and conditioning is one of the least understood processes in LIBs is, while even less is known or understood for NIBs. Kishore then reports that formation protocols for reducing formation time and maximising cycle life in a NIB comprising a Na layered oxide cathode and a HC anode. The formation comprises a series of low current (0.12 mA cm⁻², 10 mA g_{cat}⁻¹) cycles within various targeted voltage windows applied for five charge-discharge cycles which were carried out over various voltage windows described. Protocols F4 and F5 involved a narrow voltage subset of the standard voltage window and were carried out in the voltage window 1.0-1.8 and 1.8-2.6 V, and registered the minimum formation time of 6 and 17 h respectively. However, the F4 and F5 cells showed the worst cell performance in terms of capacity retention after 150 cycles (51.1% and 54.3% respectively). The best results were for F2 formed with low current and voltage between 3.6-3.8 V which exhibited 9.2% capacity fade and led to a formation time of 42 hours. Kishore demonstrates the unpredictability of SEI formation on HC anodes in NIBs and the type of complexity involved in many experimental formation protocols, which may not be amenable to commercial/industrial application.

As explained above, leanings on SEI formation in LIBs and from Na/Na symmetrical cells are not directly transferrable to NIBs for various reasons as discussed above. Conventional thinking involving at low current density over multiple slow steps are typically applied to ensure the proper formation of the best SEI on a HC anode in a NIB cell.

### STATEMENTS OF THE INVENTION

In a first aspect, the invention provides an electrochemical cell, comprising:
a super concentrated sodium salt containing ionic liquid electrolyte comprising at least one ionic liquid and at least one sodium salt,
wherein sodium salt concentration in the super concentrated sodium salt ionic liquid electrolyte is 75% or greater of its saturation limit in the ionic liquid electrolyte;
a counter electrode or a positive electrode comprising an electrochemically oxidisable material that releases sodium ions from the material into the super concentrated sodium salt electrolyte in the cell during a sodiation step or a charging step, and
a hard carbon working electrode or a negative electrode that absorbs sodium ions received at the hard carbon negative electrode from the super concentrated electrolyte as reduced sodium stored in the hard carbon during a sodiation step or a charging step, wherein,
(a) the hard carbon negative electrode comprises a formed solid electrode interface (SEI) is:
   substantially free of low ordered/short range sulfur (S₈²⁻ to S²⁻) species, for example, as identified by XPS testing and etching studies;
and optionally
   substantially free of atomic nitrogen species, for example, as identified by XPS testing and etching studies;

and/or

(b) the solid electrode interface (SEI)/hard carbon electrode has interfacial resistance associated with the SEI (Rᵢₙₜ) of less than 200 Ohms after a first formation cycle as determined by electrochemical impedance spectroscopy.

In a second aspect, the invention provides a use of a super-concentrated ionic liquid electrolyte comprising a sodium salt concentration of 75% or greater of its saturation limit in the electrolyte, in a cell comprising a hard carbon working electrode or negative electrode to form a SEI on the hard carbon electrode, wherein,
(a) the hard carbon negative electrode comprises a formed solid electrode interface (SEI) is:
   substantially free of low ordered/short range sulfur (S₈²⁻ to S²⁻) species, for example, as identified by XPS testing and etching studies;

and optionally
substantially free of atomic nitrogen species, for example, as identified by XPS testing and etching studies;
and/or

(b) the solid electrode interface (SEI)/hard carbon electrode has interfacial resistance associated with the SEI (Rini) of 200 Ohms or less after a first formation cycle as determined by electrochemical impedance spectroscopy.

In a third aspect, the invention provides a cell formation method comprising the steps of:
providing a pristine cell based on sodium metal ion electrochemistry, the fresh cell comprising:
a counter electrode or a positive electrode comprising an electrochemically oxidisable material that releases sodium ions from the material into the super concentrated electrolyte in the cell during a sodiation step or a charging step,
a hard carbon working electrode or a negative electrode that absorbs sodium ions received at the hard carbon negative electrode from the super concentrated electrolyte as reduced sodium stored in the hard carbon during a sodiation step or a charging step, and
a super concentrated sodium salt containing ionic liquid electrolyte comprising at least one ionic liquid and at least one sodium salt,
wherein sodium ion concentration in the super concentrated ionic liquid electrolyte is 75% or greater of its saturation limit in the electrolyte;
producing a formed subject cell by generating a formed SEI by reduction of the electrolyte on the hard carbon electrode by polarising the pristine cell for up to 5 formation cycles at a high constant current density ranging from ½ C to 5 C, preferably 2 C, within a full voltage window for the cell,
wherein,

(a) the hard carbon negative electrode comprises a formed solid electrode interface (SEI) is:
substantially free of low ordered/short range sulfur (S₈²⁻ to S²⁻) species, for example, as identified by XPS testing and etching studies;

and optionally
substantially free of atomic nitrogen species, for example, as identified by XPS testing and etching studies;

and/or

(b) the solid electrode interface (SEI)/hard carbon electrode has interfacial resistance associated with the SEI (Rim) of 200 Ohms or less after a first formation cycle as determined by electrochemical impedance spectroscopy.

The inventors have found that high current density driven SEI formation, the produces a SEI on hard carbon (HC) that is surprisingly highly conductive and very effectively facilitates Na+ ion diffusion across electrode/electrode boundaries. The improved SEI and associated improved cell performance is demonstrated in some embodiments by stable and high performance cycling at using a C-rate of ½ C or slower (e.g. ⅕ C), the cell exhibits, on nominal rate cycling (after formation is complete), a Coulombic efficiency of greater than 99.0%, preferably 99.2% or greater, preferably 99.3% or greater, preferably 99.4% or greater, preferably 99.5% or greater, preferably 99.6% or greater, preferably 99.7% or greater, preferably 99.8% or greater, preferably 99.9% or greater. For example, in some embodiments, the cells on cycling at a nominal 1/10 C cell rate (after formation) exhibits a CE of 99.5% or greater, preferably 99.6% or greater, more preferably 99.7% or greater, most preferably 99.8% or greater, most preferably after 50, 100, 200 or 300 cycles or greater.

### BRIEF DESCRIPTION OF THE FIGURES

Embodiments of the invention will herein be illustrated by way of example only with reference to the accompanying drawings in which:

FIG. 1 illustrates voltage-time plots for first 5 cycles for all cells on same time scale (a) and placed on separate time scales (b); Galvanostatic charge/discharge curves of Na/HC cell under different C-rates ( 1/10C, 1C and 2C) at 1^{st} (c) and 5^{th} cycle (d); Enlarged galvanostatic charge/discharge curves at 6^{th} cycle for three different formed cells (e); Galvanostatic charge/discharge of Na/HC half cell at 1^{st} and 5^{th} cycle, the current density is 0.1 C (1 C=300 mAh/g) (f); CV curves of Na/HC half-cell at 1^{st} and 5^{th} cycle with scan rate of 0.1 mV/s (g);

FIG. 2 illustrates dQ/dV vs. V curves of Na/HC cells under different C-rates at 1^{st} cycle (d)-(f) and 5^{th} cycle (g)-(i); dQ/dV vs. V curves of Na/HC cells under different C-rates 2 C cell at 2^{nd}-4^{th} cycle (h)-(k); 1 C cell at 2^{nd}-4^{th} cycle (k)-(m); 1/10 C cell at 2^{nd} to 4^{th} cycle (n)-(p);

FIG. 3 illustrates cycling stability of a Na/HC half-cell with different formation protocols. Long term discharge capacity cycling of three cells at ½ C (a) and ⅕ C (g); Long-term charge capacity cycling of three cells at ½ C (b) and ⅕ C current densities (d); Coulombic efficiency of Na/HC cells cycled at ½ C (b) and ⅕ C current densities (h); inset pictures in (a, b, g, h) are the selected cycles for cycling and CE. Cumulative irreversible capacity (e) of three formation cells for the beginning 10 cycles; long term cycling of 2 C formation cell at ½ C current density (f); Galvanostatic charge/discharge curves at 50^{th} cycle and 300^{th} cycle for 2 C formation cell (i); Cycling stability of Na/HC cell at different formation rates (2 C, 3 C and 10 C, 1C=300 mA), followed by the ½C for long term cycling; inset picture is the enlarged area of cycling stability of 2C and 3C cell from 20^{th}-40^{th} cycles (j);

FIG. 4 illustrates a three-electrode EIS measurement of HC anodes in Na/HC cells with different formation processes (2 C, 1 C and 1/10 C) for 5 cycles (a-c); EIS resistance with fitted results of three cells after 1st, 2nd and 5^{th} formation cycles (d-f);

FIG. 5 illustrates XPS spectra of HC anode after the first 5 formation cycles under the 3 different C rates examined: C 1s (a), N 1s (b) and S 2p (c). Inset picture in (c) is the enlarged area of 1/10C formation cell between 156-164 eV where the small sulfur species occur; C 1s spectra of pristine, 1/10 C, 1 C and 2 C samples (d); O 1s spectra of pristine, 1/10 C, 1 C and 2 C samples (e); C 1s spectra of three formation protocols after different etching times, 0 min, 2 min, 10 min and 40 min (f)-(h);

FIG. 6 illustrates XPS etching depth profile in terms of etching time (mins) and etching depth (nm) of the 2C formation cell after 5 formation cycles (a), 1C formation cell after 5 formation cycles (b), 1/10C formation cell after 5 formation cycles (c), and a pristine cell (d); schematic illustration of SEI formation on hard carbon anodes with different formation cells (e); Etching depth of N 1 s of hard carbon for 1/10 C cell (f), enlarged area between 400-404 eV (g);

FIG. 7 illustrates charge-discharge curves for 6^{th} formation cycle for the 1/10C formed test cell, and the 1 C and 2C formed subject cells are show in FIG. 7(a). An expanded region of the curve in (a) is illustrated in FIG. 7(b);

FIG. 8 illustrates a cycling plot of irreversible capacity versus cycle number for the formed 1/10 C test cell and the formed 1C cell (a) and 2C subject cell (b); Rate capability test of 2 C and 1/10 C formation cells at various current densities, 1/10, ⅕, ½, 1, 2, 4 C (1C=300 mAh/g) (c), enlarged rate capability of 2 C and 1/10 C formation cells at 1/10, ⅕ and ½ C. The mass loading of the HC is 0.8 mg/cm² (d);

FIG. 9 illustrates a graph showing cumulative irreversible capacity over various cycles;

FIG. 10 illustrates fitted and raw EIS data for different formation cells at different cycles: 2 C cell at 1^{st}, 2^{nd} and 5^{th} cycle (a-c); 1 C cell at 1^{st}, 2^{nd} and 5^{th} cycle (d-f); 1/10 C cell at 1^{st}, 2^{nd} and 5^{th} cycle (g-i);

FIG. 11 illustrates ex-situ²³Na (a) and ¹⁹F (b) MAS NMR spectra of electrodes cycled under different C-rate formation protocols for 5 cycles (the electrodes are at the charged state), HC soaked into electrolytes, and neat ILs are included as well.

### DETAILED DESCRIPTION OF THE INVENTION

The invention relates to an electrochemical cell, comprising:
a super concentrated sodium salt containing ionic liquid electrolyte comprising at least one ionic liquid and at least one sodium salt, wherein sodium ion concentration in the super concentrated ionic liquid electrolyte is 75% or greater of its saturation limit in the electrolyte;
a counter electrode or a positive electrode comprising an electrochemically oxidisable material that releases sodium ions from the material into the super concentrated electrolyte in the cell during a sodiation step or a charging step, and
a hard carbon working electrode or a negative electrode that reduces and absorbs sodium ions received at the hard carbon negative electrode from the super concentrated electrolyte as sodium metal stored in the hard carbon during a sodiation step or a charging step, and wherein
the hard carbon negative electrode comprises a formed solid electrode interface (SEI) which is one or more of:
completely free of atomic nitrogen species as identified by a peak at a binding energy of about 396 eV in XPS testing and etching studies, and
completely free of low ordered/short range sulfur (S₈²⁻ to S²⁻) species as identified by a peak at a binding energy of about of 164 eV to 160 eV in XPS testing and etching studies.

The inventors have discovered the improved SEI is a thinner and/or more ionically conductive SEI, and/or wherein the SEI formed is associated with favourable (surprisingly low/reduced) interfacial resistance as indicated by low impedance compared to a cell formed at a conventional formation rate/current density. The inventors believe that the absence of low ordered/short range sulfur (S₈²⁻ to S²⁻) species in the SEIs of the fast formation cells results in a thinner SEI layer that supports faster Na+ diffusion through the SEI layer. It is also believed that absence of one or more of atomic nitrogen species in the SEI composition may also be beneficial as the XPS studies described herein show a number of compositional differences between the SEIs on hard carbon formed at slow current density ( 1/10 C) versus high current density (1 C and 2C).

Conventionally, why inorganic species as described herein are believed to possess a lower diffusion energy barrier for Na+ and would be expected to boost Na migration kinetics, the inventors have found that presence of more reduced sulfur species in the SEI make the SEI layer thicker, and actually increase the Na⁺ diffusion pathway and lower the reaction kinetics. Other species in the SEI can also add to the thickness, magnitude of the Na+ diffusion pathway, e.g., atomic nitrogen species as determined by XPS analysis. The inventors have now found that SEIs absence these species actually have thinner, more porous or less dense SEI or at least one that is otherwise more ionically conductive SEI layer formed on the hard carbon. The result is a shorter sodium ion diffusion pathway and/or one having more ionically conductive features. There is also no teaching in the prior art that one or more of the compositional SEI features described herein are important for improved SEI formation and superior cell performance of a sodium-hard carbon cell.

In some embodiments, the thickness of the SEI can be determined or at least approximated by etching studies, for example, the time to etch to see XPS signals matching the surface of the pristine electrode. Other methods can used to measure SEI thickness, including electrochemical or electron microscopy methods which can be employed. Typically, conventionally formed SEI exhibit thickness of 100s of nanometres. The inventors have published a report of etching studies for these compositions (e.g., ACS Appl. Mater. Interfaces 2021, 13, 4, 5706-5720) which describes an estimation of the SEI thickness on page 5710 using an electrochemical method. The relevant parts of which are incorporated herein by reference.

In some embodiments, the ionic conductivity of the SEI and/or interfacial resistance of the SEI can be determined or inferred by well-known methods of Electrochemical Impedance Spectroscopy (EIS). A preferred solid electrode interface (SEI)/hard carbon electrode has interfacial resistance associated with the SEI (Rᵢₙₜ) of less than 300 Ohms, more preferably less than 200 Ohms after a first formation cycle as determined by electrochemical impedance spectroscopy. At the end of the formation cycles, preferred solid electrode interface (SEI)/hard carbon electrode has interfacial resistance associated with the SEI (Rᵢₙₜ) of less than 75 Ohms and in some cases 50 Ohms, signifying ease of transport of Na⁺ through the SEI of the invention.

A substantially complete and stable improved SEI formation is indicated by the cell performance feature indicated above in the methods of the first and second aspect when compared to conventionally formed SE. In addition, or separately, a substantially complete and stable improved SEI is one that has a thinner or otherwise more ionically conductive SEI layer formed on the active material surface. A substantially complete and stable improved SEI is one having a shorter metal ion diffusion pathway and/or one having more ionically conductive features. It is believed that the shorter metal ion diffusion pathway is as a result of a thinner, or a more porous or a less dense SE, or a combination of one or more of these factors which overall result in a shorter ion diffusion path compared to the SEI formed in an otherwise equivalent cell to which the conventional formation conditions described above are applied. The generation of such an improved SEI was a surprising finding as conventional thinking for SEI formation dictates that a thick and comprehensive SEI layer which is built up very slowly and/or one involving components from film forming additives added to the electrolyte is required to ensure optimal battery performance. The present results are in complete contrast, given formation using super concentrated ionic liquid electrolyte at high current rates and fast formation time produces a better SEI that has improved ionic conductivity/shorter ion diffusion pathway (thinner, or less dense, or more porous, or all of these properties, etc.) that facilitate improved the battery performance while using up less electrolyte in SEI formation. Further, due to the less irreversible capacity loss for the cell that occurs on improved SEI formation, the cells of the invention have more starting electrolyte than conventional cells and thus will experience capacity fade due to aging more slowly and so are expected to have a longer lifetime.

Suitably, the SEI is formed in accordance with the optimised cell formation conditions described herein. Also described herein is a formed subject cell obtainable or obtained by the method of the invention.

Desirably, the improved SEI in the formed subject cell has a composition having an outer layer comprising more C-N species than the SEI of the formed test cell, as indicated by XPS testing and/or etching studies.

XPS and etching studies show that the SEI composition of the test cell formed at the 1/10 C current density have features attribute to atomic nitrogen (at binding energy of about 396 eV in the tests described herein). Desirably, XPS analysis of the SEI composition of cells formed by the methods of the invention at 1 C and 2 C are absent features ascribed to atomic nitrogen at about 396 eV.

Preferably, the improved SEI in the formed subject cell is absent small sulfur-containing species (low ordered/short range sulfur (S₈2⁻to S²⁻)) or contains less small sulfur-containing species than found in the SEI of the formed test cell, as indicated by XPS testing and etching studies. These species are associated with a thicker SEI in the 1/10 C formed cell, which has an increased Na+ diffusion pathway and lower the reaction kinetics.

Preferably, the improved SEI in the formed subject cell comprises a ratio of C and O after 40 min etching which is 1 or greater.

The above indicated compositional differences in the SEI formed at the 1/10 C rate and the higher rates of 1 C and 2 C confirm that the SEIs are different in terms of component species present.

These differences are associated with the improved performance observed for the cells formed at higher current densities.

Desirably, the improved SEI in the formed subject cell is a thinner layer than the SEI of the formed test cell, as indicated by XPS testing and etching studies and/or EIS measurements.

Also described herein is a method of identifying optimised cell formation conditions for a cell formation method of forming an improved SEI on a hard carbon anode in a sodium ion electrochemical cell preferably in a total time of 20 hours or less, preferably 10 hours or less, preferably 5 hours or less, more preferably 2.5 hours or less, the method comprising the steps of:
providing two or more fresh (pristine) cells based on sodium ion electrochemistry, wherein each fresh cell comprises:
   a counter electrode comprising an electrochemically oxidisable material capable of releasing sodium ions into a super concentrated sodium salt/ionic liquid electrolyte in the cell during cell polarisation, and
   a hard carbon working electrode for absorbing sodium metal ions received at the hard carbon working electrode from the super concentrated electrolyte as reduced sodium stored in the hard carbon working electrode, wherein the super concentrated sodium salt/ionic liquid electrolyte comprises an ionic liquid and at least one sodium salt, wherein the sodium salt concentration is 75% or greater of its saturation limit in the electrolyte;
producing a formed test cell by generating an SEI on the hard carbon working electrode of a fresh test cell by applying a cell formation process to the first fresh test cell involving:
   polarising the first fresh test cell within a full voltage window for the fresh test cell at a first current density predetermined to achieve a full discharge capacity for the fresh test cell in a period of at least 10 hours for a single discharge, more preferably at least 20 hours for a single discharge (e.g., current density equivalent to 1/10C or less, or 1/20C or less), and optionally
   identifying a presence and/or absence of one or more markers in a recorded corresponding charge-discharge cycle or related analysis which are associated with substantially complete and substantially stable SEI formation on the hard carbon electrode of the formed test cell; and if necessary,
   repeating the polarising cycle step on the resultant formed test cell at the same first current density or at a different higher or lower predetermined formation current density one or more times until the presence and/or absence of one or more markers in the recorded corresponding charge-discharge cycle or related analysis is observed and which are associated with substantially complete and stable SEI formation on the hard carbon electrode of the formed test cell;
producing a formed subject cell having an improved SEI on the working electrode of the formed subject cell by applying an improved cell formation process to a fresh first subject cell involving:
   polarising the fresh first subject cell within a full voltage window for the fresh first subject cell at a second current density which is a higher current density than that used for the fresh test cell, predetermined to achieve the cell's cut off discharge potential limit and resulting discharge capacity for the fresh first subject cell in a period of less than 5 hours for a single discharge, less than 2 hours for a single discharge, preferably 1 hour or less for a single discharge, more preferably 30 minutes or less for a single discharge, and
   identifying a presence and/or absence of one or more markers in a recorded corresponding charge-discharge cycle or related analysis which are associated with substantially complete and substantially stable improved SEI formation on the hard carbon electrode of the formed first subject cell; and if necessary
   repeating the polarising step on the resultant formed first subject cell at the same predetermined second current density or at a different higher or lower predetermined formation current density one or more times until the presence and/or absence of the one or more markers indicate substantially complete and substantially stable improved SEI formation on the hard carbon electrode of the formed first subject cell has occurred, wherein the improvement in the SEI formed on the hard carbon of the formed first subject cell is evidenced by the so formed first subject cell exhibiting a higher specific capacity and/or a higher Coulombic efficiency during cycling at a nominal C-rate for the formed first subject cell compared to the specific capacity and/or Coulombic efficiency exhibited for the formed first test cell at the same nominal C-rate.

In addition to one or more of the above-described SEI compositional features, preferably, the improved SEI on the hard carbon in the formed subject cell has a SEI composition further defined by:
having outer layers comprising more C-N species than the SEI of the formed test cell, as indicated by XPS testing and/or etching studies at the same etching time;
having a composition comprising a ratio of C and O after 40 min etching which is 1 or greater.

The comparison at nominal C rate occurs for formed cells where all other things are equal, e.g., same number of polarisation steps having been applied for both. The cell's cut off discharge potential limit is the prescribed voltage limit at which the cell discharge is considered complete and is typically one which allows the maximum useful capacity of the battery to be achieved under the typical operating conditions that will result the best performance for the cell in question and is cell chemistry dependent. There will be a corresponding cell's cut off charge potential limit at which the cell's charge is considered complete. Determining the appropriate cut off potential limits for any cell is within the normal remit of the skilled electrochemist. The C rate is a measure of the rate at which the battery is charged or discharged relative to its maximum capacity. For example, 1C means the necessary current is applied or drained from the battery to completely charge it or discharge it in one hour, whereby for 1/10C, current is applied/drained in 10 hours, whereby at 2C, the current is applied/drained in 30 minutes to completely charge or discharge the battery to the chosen voltage cut off point. C rate is used here as the amount of active material used in the electrode is small. However, the required current density to result in full charge/discharge can easily be determined electrochemically for electrodes using larger amounts of active material.

In some embodiments, the cell according to the invention is capable of operating at temperatures between −20° C. and 150° C., for example between −10° C. and 150° C., between 0° C. and 150° C., between 00C and 1250C, between 0° C. and 100° C., between 0° C. and 75° C., between 0° C. and 50° C., or between 0° C. and 25° C.

Preferably, in the optimisation method of the invention, the method may further comprise the additional step of:
producing a further formed second subject cell having an improved SEI on the working electrode of the formed second subject cell by applying a cell formation process to one or more fresh subject cells involving:
   polarising the fresh second subject cell within a full voltage window for the fresh second subject cell at a third current density which is higher than the second current density above which is predetermined to achieve the cell's cut off discharge potential limit and resulting discharge capacity for the fresh second subject cell in a period of less than that selected for the method of the first aspect, and
   identifying a presence and/or absence of one or more markers in a recorded corresponding charge-discharge cycle or related analysis which are associated with substantially complete and substantially stable further improved SEI formation on the hard carbon electrode of the formed second subject cell; and if necessary
   repeating the polarising step on the resultant formed second subject cell at the same predetermined third higher current density or at a different higher or lower predetermined formation current density one or more times until the presence and/or absence of the one or more markers indicate substantially complete and stable improved SEI formation on the hard carbon electrode of the formed second subject cell has occurred,
wherein the improvement in the SEI formed on the hard carbon of the formed second subject cell is evidenced by the so formed second subject cell exhibiting a higher specific capacity and/or a higher Coulombic efficiency during cycling at a nominal C-rate for the formed subject cell compared to the specific capacity and/or Coulombic efficiency exhibited for the formed test cell and the formed first subject cell at the same nominal C-rate. It will be understood that this comparison at nominal C rate occurs for formed cells where all other things are equal, e.g., same number of polarisation steps having been applied for both.

Further improvements in the method may be achieved by repeating this step on yet a further fresh third subject cell or one or more subsequent fresh additional subject cells as necessary, whereby further improvement in the SEI formed are indicated by observation of further improved performance at the nominal C-rate for the cell.

In some embodiments up to 5, or 5 formation cycles are required to produce the substantially complete and substantially stable SEI. It will be understood that 5 cycles each involving a period of at least 10 hours for a single discharge stage for each of the 5 polarisation cycles would require a total time of 5×20 hours which is a total formation time of 100 hours. In contrast, 5 cycles each involving a period of at 5 or less hours for a single discharge stage for each of the 5 polarisation cycles would require a total time of 5×10 hours which is a total formation time of 50 hours which is half the total time for a conventional formation protocol. Likewise, in contrast, 5 cycles each involving a period of at 30 minutes for a single discharge stage of the 5 polarisation cycles would require a total time of 5×0.5 hours which is a total formation time of 2.5 hours, that is a factor of 40× faster whilst producing better performance during cycling at a nominal C-rate that an equivalent cell formed in a total time of 100 hours.

Also described herein is a cell formation method of forming an improved SEI on a hard carbon anode in sodium ion electrochemical cell in in a total time of 20 hours or less, preferably 5 hours or less, more preferably 2.5 hours or less, the method comprising the steps of:
providing a fresh cell based on sodium ion electrochemistry, the fresh cell comprising:
   a counter electrode comprising an electrochemically oxidisable material capable of releasing sodium ion into a super concentrated electrolyte in the cell during cell polarisation, and
   a hard carbon working electrode for absorbing sodium ions received at the hard carbon working electrode from the super concentrated electrolyte as reduced sodium stored in the hard carbon working electrode, wherein the super concentrated sodium ion ionic liquid electrolyte comprises an ionic liquid and at least one sodium salt, wherein the sodium salt concentration is 75% or greater of its saturation limit in the electrolyte;
producing aformed subject cell having an improved SEI on the working electrode of the formed subject cell by applying a cell formation process to a fresh subject cell by
   polarising the fresh subject cell at a predetermined formation current density which achieves the cell's cut off discharge potential limit and resulting discharge capacity for the fresh subject cell in a period of less than 5 hours for a single discharge, less than 2 hours for a single discharge, preferably 1 hour or less for a single discharge, more preferably 30 minutes or less for a single discharge, and
   identifying a presence and/or absence of one or more markers in a recorded corresponding charge-discharge cycle or related analysis which are associated with substantially complete and stable SEI formation on the hard carbon electrode; and if necessary,
   repeating the polarising step on the resultant formed subject cell at the same predetermined formation current density one or more times until the presence and/or absence of the one or more markers indicate occurrence of substantially complete and stable improved SEI formation on the hard carbon electrode of the formed subject cell,
wherein the predetermined formation current density and/or number of polarisation cycle repeats required for producing the improved SEI are identified by the method of the first aspect.

Preferably, in the method of the invention, cell polarisation occurs by galvanostatically charging and discharging each cell.

Electrochemical Impedance Spectroscopy (EIS) can be used to indicate the interfacial resistance on the hard carbon surface at different current densities.

Also described herein is a formed subject cell obtainable and/or obtained by the methods of the invention. Preferably, the SEI composition of the cell is defined according to the first aspect indicated above.

The inventors have developed a new formation protocol for improved SEI formation and improved electrochemical cell performance in sodium ion based cell comprising a hard carbon working electrode (or negative electrode in a battery) and a super-concentrated sodium salt/ionic liquid electrolyte. The invention extends to cells produced by a formation method as described herein using unconventionally high current densities in formation polarisation cycles involving a full voltage window for the cell in question. Proof of concept is demonstrated by half-cell studies involving sodiation of a hard carbon negative electrode though hard carbon is suitable for use in full cell sodium-ion batteries. Using the methods of the invention, sodiation of pristine hard carbon is accompanied by substantially complete SEI formation during the first formation cycle, and in some cases, fully complete in the first few formation cycles, typically fully complete after 5 formation cycles. It will be understood that the formation process results in the hard carbon electrode having a SEI formed thereon between the electrode surface and the electrolyte (at the interface) as a result of the electrochemical cell having undergone at least one polarisation cycle, and in some embodiments, up to 10 polarisation cycles, preferably, up to 10, up to 9, up to 8, up to 7, up to 6, up to 5, up to 3 formation cycles. Methods where less polarisation cycles are preferred to form a substantially complete and substantially stable SEI are preferred as this results in a shorter overall formation time.

The inventors have also developed a method for identifying the optimum formation conditions/parameters required for use in the preferred formation methods of the invention where the desired degree of SEI formation can be achieved in unconventional short total formation periods of time of 20 hours or less, preferably 5 hours or less, more preferably 2.5 hours or less, involving 5 full formation cycles to ensure a fully complete SEI formation. However, in some methods, the formation period is even shorter, where the SEI is full formed after just one or two high current density polarisation cycles as described herein. The improved methods can generate substantially complete and substantially stable SEI formation through application of from about 1 or 2 to 5 formation cycles as described herein, where it will be understood that each polarisation cycle includes a discharge stage that is 5 hours or less for a single discharge, preferably 2 hours or less for a single discharge, preferably 1 hour or less for a single discharge, more preferably 30 minutes or less, and in some cases 15 minutes or less for a single discharge step. It will be understood that the high current densities required (½ C to 5 C) to support this fast cycling means that the cut off potential limit for the cell is reached with corresponding relatively low capacities compared to the full discharge capacities possible using conventional polarisation/cycling rate of at least 10 hours for a single discharge, more preferably at least 20 hours for a single discharge. As ⅔ such slow cycles are used for conventional formation methods, the total formation time takes from about 40 to 120 hours. In contrast, the formation methods of the invention are much shorter, whereby a substantially complete and stable SEI can be formed in, for example, about 5 cycles of in a period of 5 hours or less for a single discharge, preferably 2 hours or less for a single discharge, preferably 1 hour or less for a single discharge, more preferably 30 minutes or less for a single discharge leading to a total formation time of only 20 hours or less, preferably 5 hours or less, more preferably 2.5 hours or less, depending on the current density selected for the method.

Desirably, the method does not include a rest period between successive charge and discharge cycles or successive full cycles of a single charge and discharge cycle. In some preferred embodiments, complete and stable SEI formation occurs in 4 formation cycles or less, preferably 3 formation cycles or less, preferably 2 formation cycles or less, and in some particularly preferred cycles, after 1 formation cycle.

In some preferred embodiments, the formation protocols described herein can shorten the SEI formation and conditioning time on a hard carbon negative electrode compared to conventional formation protocols (e.g., involving a current density giving a full discharge capacity at a rate of 1/10C or less or 1/20 C or less or the current density equivalent), preferably by at least factor of about 10×, and preferably at least a factor of about 15× and more preferably a factor of about 20× (e.g., that is up to about 20 times faster than a conventional formation method) and in some cases up to 38× times faster. The cost savings and efficiency increase resulting from the methods of the invention is clear.

The invention thus provides a new and unconventional cell formation method involving forming an improved SEI on a hard carbon electrode, in NIB cell in a total time of 20 hours or less.

The substantially complete and substantially stable improved SEI formed in the unconventionally short periods of time is a high performing/improved SEI that is at least as good as a SEI formed in an identical cell (same chemistry, materials, fabrication, batch etc) using conventional, but much slower formation methods as described above (e.g., ⅔ polarisation cycles at 1/10 C or 1/20 C rates). “At least as good” means the SEI will have the same, if not better (higher) ionic conductivity, and/or the same if not better (lower) impedance than an SEI that formed using a conventional formation method involving polarisation utilising at least 10 hours for a single discharge, more preferably at least 20 hours for a single discharge (where all other things are equal). However, a preferred formation method of the invention produces an improved SEI which is a substantially complete and substantially stable SEI in a total time of 20 hours or less, which has been found to result in a SEI with a higher ionic conductivity and/or a lower impedance than the SEI that would have been formed using a conventional formation method as described above. It follows that the improved SEIs of the invention are different compositionally, and/or different structurally and/or different in terms of mechanical properties, and/or chemical properties such as composition, physical properties such as one or more of thickness, porosity, density etc., as well as electrical properties such as impendence and sodium ion ionic conductivity of the SEI than the SEI of an equivalent cell formed at the much slower rates. It is believed that the SEI of the invention has one or more of the following feature: being substantially free of atomic nitrogen species, for example, as identified by XPS, such as by a peak at a binding energy of about 396 eV in XPS testing and etching studies, and low ordered/short range sulfur (S₈²⁻ to S²⁻) species, for example, as identified by XPS, such as by a peak at a binding energy of about of 164 eV to about 160 eV in XPS testing and etching studies. Furthermore, the formation methods described herein result in formed cells (as a result of improved SEI formation as well as reduced electrolyte consumption with less associated irreversible capacity loss during formation) that exhibit superior performance compared to conventionally formed cells at the rates described above. Advantageously and surprisingly, the improved performance improvements observed are attained despite the formation time being a factor up to about 20 times faster than conventional formation protocols (e.g., using formation cycling involving a single discharge time of 10 hours or more, and more typically 20 hours for a single discharge cycle, at least 2 or 3 of which are required for good SEI formation). The results are surprising as the methods go against the conventional thinking in the art that would lead away from using very high current densities during formation. There is also no teaching in the prior art that the compositional SEI features described herein are important for improved SEI formation and superior cell performance of a sodium-hard carbon cell.

### Cell Formation Conditions

The method involves a step of producing a formed test cell by generating a (“conventional”) SEI on the working electrode of a first fresh cell by applying a cell formation process to the fresh cell, whereby the formed test cell is subjected to a conventional set of formation method conditions at a typically slow/low rate which is a conventional rate in which the discharge step of a single polarisation cycle takes 10 hours or more, or even 20 hours or more. for a single discharge step of a single polarisation cycle. Implementing a conventional cell formation step is an optional but useful step as it provides an indication of SEI behaviour at the low current density (that is slow rate, such as 1/10C or 1/20C) used for a typical SEI formation occurring under conventional conditions. This indication is useful to set the initial improved formation conditions according to the invention which are desired to involve shorter discharge cycles possible at higher current densities. This allows higher current densities used in the formation method of the invention to be readily determined. For example, electroanalytical studies on this first formation process applied to the first fresh test cell can also provide information on the nature, stage and completeness/stability of SEI formation at the conventional rate, including identification of one or more markers that signify SEI formation is occurring and/or the extent of SEI formation, such as degree of completeness and/or stability of the SEI formed, as well as information as to the ionic conductivity and/or impedance of the SEI so formed. These markers may be useful to compare the SEI formation in the subject cells to which the formation method is applied and may aid in identifying formation of a substantially complete and stable SEI has formed at the higher rate/current density conditions used in the methods of the invention. They also provide the basis for a property and/or performance comparison of the improved SEI versus a conventionally formed SEI, demonstrating the advantages of the invention. Thus, the method of the first aspect may involve establishing a baseline “conventionally” formed test cell. The method therefore in this case involves a step as follows:

Polarising the first fresh test cell within a full voltage window for the fresh test cell at a predetermined first current density to achieve a full discharge capacity for the cell in a period of at least 10 hours for a single discharge, more preferably at least 20 hours for a single discharge (e.g., current density equivalent to 1/10 C or 1/20 C discharge step), and optionally identifying a presence and/or absence of one or more markers in a recorded corresponding charge-discharge cycle or related analysis which are associated with substantially complete and stable SEI formation on the hard carbon electrode; and optionally if necessary, repeating the polarisation for the test cell at the same first current density one or more times until the presence and/or absence of one or more markers in the recorded corresponding charge-discharge cycle or related analysis is observed and which are associated with substantially complete and stable SEI formation on the hard carbon electrode of the formed fresh test cell. Conventional thinking would suggest that the 1/20 C rate would produce the best SEI for the particular test cell though a 1/10 C would also be considered to form an acceptable SEI that would support acceptable cell performance. The method of the invention may then involve a step as follows:
producing a formed subject cell by repeating step a) on subject fresh cell (identical in chemistry, properties, and make up to the fresh cell used in the first step) at a predetermined second current density which is a higher current density than that used in step a), wherein the higher current density achieves the full discharge capacity for the cell in a period of 5 hours or less for a single discharge, preferably 2 hours or less for a single discharge, preferably 1 hour or less for a single discharge, more preferably 30 minutes or less for a single discharge, until the one or more markers provide evidence of formation of a substantially complete and stable improved SEI on the hard carbon working electrode.

The subject cell is a cell to which the unconventional formation step is to be/has been applied.

If necessary (and the markers, that is presence or absence thereof, indicate it would be beneficial for further development of the SEI), the method may comprise further repeating the above producing step one or more times on the same formed subject cell at the same second current density until the one or more markers provide sufficient evidence of formation of a substantially complete and stable improved SEI on the hard carbon working electrode.

It should be noted that the improvement in the SEI formed on the hard carbon of the formed subject cell is readily evidenced where the formed subject cell exhibits a higher specific capacity and/or a higher Coulombic efficiency during cycling at a nominal C-rate for the formed subject cell compared to the specific capacity and/or Coulombic efficiency exhibited for the formed test cell. It will be understood that this comparison at nominal C rate occurs for formed cells where all other things are equal, e.g., same number of polarisation steps having been applied for both. This ensures a direct performance comparison, where the only difference is the particularly high rate/current density formation conditions and number of repeat polarisation steps applied to the formed cell.

### Forming a Cell Formation Under Optimum Formation Conditions

The invention provides a cell formation method of forming an improved SEI on a hard carbon anode in sodium ion electrochemical cell in a total time of 20 hours or less, preferably 5 hours or less, more preferably 2.5 hours or less. After the improved SEI is formed, the cell will exhibit the described performance improvements during cycling at a nominal C rate for the particular cell.

In some embodiments, a set of optimised formation conditions (e.g., once identified according to the method of the first aspect above) can be applied in a formation method applicable to an identical fresh (pristine) cell, or to a batch of identical fresh (pristine) cells such as may be encountered in commercial battery manufacture. Such formation method comprises a first step of:
providing one or more fresh cells to be formed which are based on sodium ion electrochemistry, the fresh cell comprising:
   a counter electrode comprising an electrochemically oxidisable material capable of releasing sodium ions into a super concentrated electrolyte in the cell during cell polarisation, and
   a hard carbon working electrode for absorbing sodium ions received at the hard carbon working electrode from the super concentrated electrolyte as reduced sodium stored in the hard carbon working electrode,
wherein the super concentrated sodium ion ionic liquid electrolyte comprises an ionic liquid and at least one sodium salt, wherein the sodium ion concentration is 75% or greater of its saturation limit in the electrolyte.

The formation method then involves the step of: producing a formed subject cell having an improved SEI on the working electrode of the formed subject cell by applying a cell formation process to a fresh subject cell by
polarising the fresh subject cell at a predetermined formation current density which achieves the cell's cut off discharge potential limit and resulting discharge capacity for the fresh subject cell in a period of 5 hours or less for a single discharge, preferably 2 hours or less for a single discharge, preferably 1 hour or less for a single discharge, more preferably 30 minutes or less for a single discharge; and
identifying a presence and/or absence of one or more markers in a recorded corresponding charge-discharge cycle or related analysis which are associated with substantially complete and stable SEI formation on the hard carbon electrode; and if necessary,
repeating the polarising step on the resultant formed subject cell at the same predetermined second current density or at a different higher or lower predetermined formation current density one or more times until the presence and/or absence of the one or more markers indicate occurrence of substantially complete and stable improved SEI formation on the hard carbon electrode of the subject cell,
wherein the improvement in the SEI formed on the hard carbon is evidenced by the formed subject cell exhibiting a higher specific capacity and/or a higher Coulombic efficiency during cycling at a nominal C-rate for the formed subject cell compared to the specific capacity and/or Coulombic efficiency exhibited for the formed test cell. Preferably, (i) the predetermined formation current density and/or (ii) the number of polarisation cycle repeats corresponding to a number of polarisation steps required for producing the improved SEI are identified by a method of identifying optimised cell formation conditions described in the first aspect.

Suitably the methods of the invention are carried out in a temperature range of from 0° C. to 100° C., preferably 20° C. to 85° C., more preferably 25° C. to 80° C., more preferably still 45° C. to 55° C. In some preferred embodiments, the method is carried out at 50° C. (±2%). Preferably, cell polarisation involves galvanostatically charging and discharging the fresh test cell within a full voltage window for the fresh test cell at a predetermined first current density which achieves a full discharge capacity for the cell in a period of at least 10 hours for a single discharge, more preferably at least 20 hours for a single discharge. “Charging” the cell refers to polarisation of the cell such that ions are reduced at the working electrode (i.e., sodiation or lithiation etc), while “discharging” is the reverse process of oxidation at the working electrode (i.e., de-sodiation, de-lithiation etc).

In some embodiments, during polarisation, the current density is selected so that the cell's cut off discharge potential limit and resulting discharge capacity is reached in a period of less than 5 hours for a single discharge, less than 2 hours for a single discharge, preferably 1 hour or less for a single discharge, more preferably 30 minutes or less for a single discharge. It will be understood that the desired formation time guides the level of current density used to achieve full discharge in the above-described methods.

In embodiments, the formation time means the time required for a substantially complete, substantially stable improved SEI to form on the hard carbon working electrode which is characterised by meeting the above described performance requirements for the cell. In short, in some embodiments, a substantially stable improved SEI is one that is complete enough to support a higher performance when the formed subject cell exhibits a higher specific capacity and/or a higher Coulombic efficiency during cycling at a nominal C-rate for the formed subject cell compared to the specific capacity and/or Coulombic efficiency exhibited for the formed test cell. In some preferred embodiments, the higher performance of the formed subject cell compared to the test cell can be observed after up to at least 50 cycles, at least 100 cycles, at least 200 cycles, at least 500 cycles, at least 1000 cycles, at least 2000 cycles, at a nominal C-rate. C-rate is defined as the charge/discharge current divided by the nominally rated battery capacity. For example, a 5,000 mA discharge on a 2,500 mAh rated battery would be a 2C rate such that full discharge would occur in 30 minutes. Likewise, a 2,500 mA discharge on a 2,500 mAh rated battery would be a 1C rate, such that full discharge would occur in 1 hour. Likewise, a 250 mA discharge on a 2,500 mAh rated battery would be a 1/10C rate, such that full discharge would occur in 10 hours.

Desirably, the current density applied during the method is a constant current density.

Suitably, the hard carbon working electrode comprises hard carbon, more preferably consists essentially of hard carbon.

In some embodiments, the second current density achieves the cut off discharge potential limit for the cell in a period of 5 hours or less for a single discharge step of a polarisation cycle. In some embodiments, the second current density achieves the cut off discharge potential limit for the cell in a period of 2 hours or less for a single discharge step of a polarisation cycle. In some embodiments, the first predetermined current density at the working electrode in the formation step for the test cell is 200 mA/g or less, 150 mA/g or less, 100 mA/g or less, 50 mA/g or less, 10 mA/g or less. In some embodiments, the first predetermined current density at the working electrode in the formation step for the test cell is about 50 mA/g to about 100 mA/g. In some embodiments, the second or third or further higher current density at the working electrode in the formation step for the first subject cell is about 350 mA/g or more, about 375 mA/g or more, about 400 mA/g or more, about 450 mA/g or more, about 500 mA/g or more, about 550 mA/g or more, about 600 mA/g or more, about 650 mA/g or more, about 700 mA/g or more, about 750 mA/g or more, about 800 mA/g or more, about 850 mA/g or more, about 900 mA/g or more.

In particular, for the C₃mpyrFSI based super-concentrated ionic liquid described in the present examples, the 1/10C rate required a current density of 30 mA/g for full discharge, the 1 C rate required a current density of 300 mA/g, and the 2 C rate required a current density of 600 mA/g.

The “super-concentrated” ionic liquid based electrolyte comprises an sodium ion ionic liquid electrolyte which is suitable for use in a cell of the invention and are not particularly limited, provided cell criteria is met and they present in liquid form at the temperature of use of the cell. Suitably, the “super-concentrated” ionic liquid based electrolyte is dry, in that it contains<50 ppm water. The ionic liquid of the super concentrated electrolyte preferably comprises pyrrolidinium cation, preferably, an alkylated-pyrrolidinium cation, preferably a 1-methyl-1-alkyl-pyrrolidinium cation (C₃mpyr⁺), most preferably a 1-methyl-1-propyl-pyrrolidinium cation (C₃mpyr⁺). However, for sodiation of hard carbon the preferred electrolyte is a C₃mpyrFSI based super-concentrated ionic liquid, particularly that described in the present examples.

Otherwise, the sodium salt/ionic liquid electrolyte used in accordance with the invention may comprise one or more organic salts selected from 1-butyl-3-methylimidazolium bisulfate ([C₄mim][HSO₄]), 1-alkyl-3-methylimidazolium bromide ([Cₙmim][Br]), 1-hexadecyl-3-methylimidazolium chloride ([C₁₆mim][Cl]), 1-octyl-3-methylimidazolium chloride ([Cₙmim][CI]), 1-butyl-3-methylimidazolium tetrafluoroborate ([C₄mim][BF₄]), 1-octyl-3-methylimidazolium tetrafluoroborate ([C₈mim][BF₄]), 1-ethyl-3-methylimidazolium bis(tri-fluoromethanesulfonyl)imide ([C₂mim][Tf₂N]), 1-butyl-3-methylimidazolium chloride ([C₄mim][C]), 1-hexyl-3-methylimidazolium tetrachloroferrate(III) ([C₆mim][FeCl₄]), 1-propyl-3-methylimidazolium iodide ([C₃mim][I]), 1-ethyl-3-methylimidazolium trifluoromethanesulfonate ([C₂mim][OTf]), 1-alkyl-3-methylimidazolium triflate ([Cₙmim][Tf]), 1-ethyl-3-methylimidazolium acetate ([C₂mim][OAc]), N-butyl-N-methylpyrrolidinium bis(trifluoromethanesulfonyl)amide(([C₄mPyr][Tf₂N]) or ([C₄mpy][Tf₂N])), 1-ethyl-3-methylimidazolium tetralluoroborate ([C₂mim][BF₄]), 1-dodecyl-3-methylimidazolium bromide ([C₁₂mim][Br]), 1-octyl-3-methylimidazolium bis(tri-fluoromethanesulfonyl)imide ([C₈mim][Tf₂N]), 1-hexadecyl-3-methylimidazolium bis(tri-fluoromethanesulfonyl)imide ([C₄mim][Tf₂N]), 1-ethyl-3-methylimidazolium chloride ([C₂mim][CI]), 1-(3-aminopropyl)-3-methylimidazolium bromide ([(3-aminopropyl)mim][Br]), 1,2-dimethyl-3-butylimidazolium bis(trifluoromethanesulfonyl)amide ([C₄(2-Ci)mim][Tf₂N]), 1-butyl-3-methylimidazolium dicyanamide ([C₄mim][N(CN)₂]), 1-hexadecyl-3-methylimidazolium tetrafluoroborate ([C₄mim][BF₄]), 1-butyl-3-methylimidazolium hexafluorophosphate ([C₄mim][PFe]), 1-butyl-3-methylimidazolium bis(trifluoromethanesulfonyl)imide ([C₄mim][Tf₂N]), 1-butyl-1-methylpyrrolidinium bis(triiluoromethanesulfonyl)imide ([C₄mpyr][Tf₂N]), 1-butyl-3-methylimidazolium tetrachloroferrate(III) ([C₄mim][FeCl₄]), 1-ethyl-3-methylimidazolium bromide ([C₂mim][Br]), 1-hexadecyl-3-methylimidazolium bromide ([C₁mim][Br]), 1,2-dimethyl-3-(3-hydroxypropyl)imidazolium bis(trifluoromethanesulfonyl)imide (C₂—OH)N-ethyl-tris(2-(2-methoxyethoxy)ethyl)ethane ammonium bis(fluorosulfonyl)imide ([N₂(20201)₃][FSI]) and N-ethyl-tris(2-(2-methoxyethoxy)ethyl)ethane ammonium bis(trifluoromethanesulfonyl)imide ([N_{2(2P2O1)3}][TFSI]).

In some embodiments, the sodium salt/ionic liquid electrolyte used in accordance with the invention may comprise one or more organic salts comprising a salt selected from bis(tri-fluoromethanesulfonyl)imide ([Tf₂N], or [TFSI]), bis(fluorosulfonyl)imide ([FSI]), or combinations thereof.

For example, the organic salt comprises 1-butyl(propyl)-1-methylpyrrolidinium bis(trifluoromethylsulfonyl)imide ([C₄C₃mpyr][TFSI]), and N-methyl-N-propylpyrrolidinium bis(fluorosulfonyl)imide ([C₃mpyr][FSI]). Organic salts suitable for use to form the electrolyte of the invention may also comprise those disclosed in Gebrekidan Gebresilassie Eshetu, Michel Armand, Bruno Scrosati, and Stefano Passerini, Energy Storage Materials Synthesized from Ionic Liquids Angewandte Chemie Int. Ed. 2014, volume 53, page 13342, the content of which is included herein in its entirety.

Desirably, the electrolyte comprises a phosphorous-based organic salt. That is, the sodium ion ionic liquid electrolyte used in accordance with the invention may also comprise one or more organic salts selected from phosphorous analogues of the organic salts disclosed herein. By phosphorous “analogues” of the organic salts disclosed herein it is meant organic salts sharing the same chemical structure as the organic salts disclosed herein with phosphorous atoms replacing the nitrogen atoms.

Accordingly, the electrolyte used in accordance with the invention may comprise one or more organic salts selected from trihexyl(tetradecyl)phosphonium bis(trifluoromethanesulfonyl)imide ([P₆₆₆₁₄][Tf₂N]), trihexyl(tetradecyl)phosphonium bis(fluorosulfonyl)imide ([P₆₆₆₁₄][FSI]), diethyl(methyl)(isobutyl)phosphonium bis(trifluoromethanesulfonyl)amide ([P₁₂₂₄][Tf₂N]), diethyl(methyl)(isobutyl)phosphonium bis(fluoromethanesulfonyl)amide ([P₁₂₂₄][FSI]), triisobutyl(methyl)phosphonium bis(trifluoromethanesulfonyl)imide ([P₁₂₂₄][Tf₂N]), triisobutyl(methyl)phosphonium bis(fluoromethanesulfonyl)imide ([P₁₄₄₄][FSI]), triethyl(methyl)phosphonium bis(trifluoromethanesulfonyl)imide ([P₁₂₂₂][Tf₂N]), triethyl(methyl)phosphonium bis(fluoromethanesulfonyl)imide ([P₁₂₂₂][FSI]), trimethyl(isobutyl)phosphonium bis(trifluoromethanesulfonyl)imide ([P₁₁₁₄][Tf₂N]), and trimethyl(isobutyl)phosphonium bis(fluoromethanesulfonyl)imide ([P₁₁₁₁₄][FSI]).

The electrolyte used in accordance with the invention may also comprise one or more organic salts selected from those described herein that incorporate an alkoxy ether functionality in the cation side chain (e.g., by replacing an alkyl chain on the cation).

In some embodiments, the electrolyte used in accordance with the invention comprises one or more sodium salts selected from sodium bis(tri-fluoromethane)sulfonimide (Na[TFSI]), sodium (bis(fluorosulfonyl)imide (Na[FSI]), sodium triflate (NaOTf), sodium perchlorate (NaClO₄), sodium tetrafluoroborate (NaBF₄) and sodium hexafluorophosphate (NaPF₆).

Desirably, wherein the sodium ion is Na+, the electrolyte comprises Na[TFSI] and [C₃mpyr][TFSI], Na[TFSI] and [C₄C₃pyr][TFSI], Na[TFSI] and [C₃mpyr][FSI], Na[TFSI] and [C₄C₃mpyr][FSI], Na[FSI] and [C₃mpyr][TFSI], Na[FSI] and [C₄C₃mpyr][TFSI], Na[FSI] and [C₃mpyr][FSI], Na[FSI] and [C₄C₃mpyr][FSI], or combinations thereof.

Desirably, the electrolyte comprises sodium(bis(fluorosulfonyl)imide (Na[FSI]) and N-propyl-N-methylpyrrolidinium bis(fluorosulfonyl)imide (C₃mpyr[FSI]).

Other suitable ionic liquids include oxazolidinium cations such as [C₁moxa]+, [C₂moxa]+; ammonium cations such as [N_{111.1O1}], or ammoniums with functional groups such as cyanoammonium, morpholiniums; charge diffuse cations such as hexamethylguanidinium; pyrrolidiniums such as [C₂epyr]⁺, [C₍₃₎mpyr]. These cations can be used with any suitable anion but particularly TFSI⁻, FSI⁻, BF₄⁻ or PF₆⁻anions. Particularly preferred for this invention are ILs having cations comprising HMG (hexamethyl guanidinium), oxa (dimethyl oxazolidinium etc) and ammoniums (e.g., tetra methyl and methyl, triethyl etc) with FSI and TFSI in particular.

According to the invention the sodium salt concentration in the electrolyte is no less than 75% of its saturation limit in the electrolyte. The concentration of sodium salt in the electrolyte is the mol % of sodium salt relative to the total moles of sodium salt and organic salt. “Saturation limit in the electrolyte” means the highest concentration of sodium salt in the electrolyte at which there is no precipitation of sodium salt out of the electrolyte at a given temperature. In other words, the sodium salt concentration is at its saturation limit in the electrolyte at a given temperature if further sodium salt added into the electrolyte will not dissolve. The saturation limit of sodium salt ion in the electrolyte at a reference temperature is the concentration that can be conveniently measured according to standard procedure known in the art. According to such procedure a progressively increasing amount of sodium salt is added to the organic salt at an initial temperature, the initial temperature being higher than the reference temperature at which the saturation limit is to be determined. The addition of sodium salt continues until formation of a visible precipitate of undissolved salt, indicating that the saturation limit is exceeded. The temperature is then decreased to the reference temperature, resulting in further sodium salt precipitating out of the organic salt. Once precipitation of sodium salt ceases the total amount of sodium salt precipitate is determined by separating the precipitate from the solution using means that would be known to the skilled person. The sodium salt saturation limit at the reference temperature is calculated as the difference between the total sodium salt added to the organic salt and the amount of sodium salt precipitate.

“No less than 75% of its saturation limit in the electrolyte” means a sodium salt concentration within a range of from 75% to 100% of its saturation limit in the electrolyte. For example, if at a given temperature the saturation limit of sodium salt in the electrolyte is 60 mol %, then the sodium salt concentration in the electrolyte according to the invention would be no less than 45 mol % (45 mol % being 75% of 60 mol %). In other words, in that example the concentration of the sodium salt in electrolyte according to the invention would be within a range of from 45 mol % to 60 mol %.

The saturation limit of the electrolyte is that which presides at the operating temperature of the cell. “Operating temperature of the cell” means the temperature at which the cell is put into function, e.g., when the SEI layer is formed, during discharge while powering an external load attached to the electrodes, and/or during charge. In other words, at the operating temperature of the cell the sodium salt/ionic liquid electrolyte has sodium salt concentration that is no less than 75% of its saturation limit in the electrolyte.

Preferably, the sodium salt concentration in the super concentrated ionic liquid based electrolyte is 80% or greater, 85% or greater, 90% or greater, 95% or greater, or 100% of its saturation limit in the electrolyte. Preferably, the sodium salt concentration in the super concentrated ionic liquid based electrolyte is 40 mol % or more, 50 mol % or more, 60 mol % or more, 70 mol % or more, 80 mol % or more, 90 mol % or more, or 95 mol % or more. In some embodiments, the concentration of sodium salt in the electrolyte is no less than 76%, no less than 77%, no less than 78%, no less than 79%, no less than 80%, no less than 81%, no less than 82%, no less than 83%, no less than 84%, no less than 85%, no less than 86%, no less than 87%, no less than 88%, no less than 89%, no less than 90%, no less than 91%, no less than 92%, no less than 93%, no less than 94%, no less than 95%, no less than 96%, no less than 97%, no less than 98%, or no less than 99% of its saturation limit in the electrolyte. In some embodiments, the concentration of sodium ion in the electrolyte is at its saturation limit.

In addition to being no less than 75% of its saturation limit in the electrolyte, in some embodiments the sodium salt concentration in the electrolyte may also be 40 mol %, 50 mol %, or higher. For example, the molar concentration of the sodium salt in the electrolyte may be at least 40 mol %, 50 mol %, 55 mol %, 60 mol %, 65 mol %, 70 mol %, 80 mol %, or 90 mol %.

In some embodiment, the cell is in a half cell configuration. For example, where the cell is in a half cell configuration, the counter electrode is sodium metal, and the working electrode is the negative material, e.g., hard carbon. In other embodiments, the cell is in a full cell configuration. For example, the cell may be in a full cell configuration and the counter electrode comprises, or is composed of, a material that can reversibly intercalate/deintercalated sodium ions within their atomic structure, absorb/desorb sodium ions by reversible oxidation/reduction reactions, or promote alloying/dealloying reactions with sodium ions.

In some embodiments, the counter electrode comprises, or is composed of, Na_{0.4}Ni_{0.22}Co_{0.11}Mn_{0.66}O₂, Na_{2/3}Fe_{2/3}Mn_{2/3}(O₃), Na_{2/3}Fe_{2/3}Mn_{1/3}O₂ (P2), olivine-type NaFePO₄, NaₓFePO₄, silicates, Nasicon type phases of general formula Na₂M₂(XO₄)₃(M=transition metal and X═P, S).

In a preferred embodiment, the predetermined first current density of step a) achieves a full discharge capacity for the cell in a period of 10 hours, corresponding to a conventional formation process, using a 1/10 C rate for formation. In a preferred embodiment, wherein the predetermined constant second higher current density of step b) achieves a full discharge capacity for the cell in a period of 0.5 hours or less. In a preferred embodiment, the predetermined constant second higher current density of step b) achieves a full discharge capacity for the cell in a period of 0.25 hours or less. Where the period is desired to be 0.25 hours or 0.5 hours, it is most preferred to use a 10 hour or less period in step a).

Desirably, the nominal C-rate for the formed subject cell is ½ C or ⅕ C, though any particularly desired suitable nominal C-rate can be used so long as the same C-rate is applied to the formed test cell of step a). Preferably, the formed subject cell may be further galvanostatically cycled at the lower C-rate for up to 100 cycles, preferably up to 50 cycles, for the purposes of comparing performance to the formed test cell.

Preferably, during nominal C-rate cycling (after SEI formation is complete), the formed subject cell exhibits a Coulombic efficiency (CE) of 99.2% or greater, preferably 99.3% or greater, preferably 99.4% or greater, preferably 99.5% or greater, preferably 99.6% or greater, preferably 99.7% or greater, preferably 99.8% or greater, preferably 99.9% or greater from the 20^{th} cycle onwards, more preferably from the 10^{th} cycle onwards, more preferably still from 6^{th} cycle onwards (in the case of a 5 formation cycle process). The performance is preferably compared to the formed test cell after 10 or more, 50 or more, or 100 or more cycles at the nominal selected C-rate for the cells. The higher the CE after formation during cycling at nominal C rate, the better, as given irreversible capacity loss or fade occurs as a cell ages, the small drop in a CE away from unity accumulates as the cell is cycled and so capacity fade that inevitably occurs later in cycling as the cell ages becomes more dramatic earlier on, where the starting CE is closer to 99% than to 100%. Thus, given their higher CE during early nominal C rate cycling, the cells of the invention will exhibit an overall longer cycle life (number of achievable cycles) prior to reaching a decided end of life capacity loss point.

Desirably, the one or more markers (e.g., in the recorded corresponding charge-discharge cycle or related analysis) associated with substantially complete and stable SEI formation on the hard carbon electrode include:

(a) Discharge-charge curve markers/features
observation lack of significant and/or observation of substantially static, electrolyte reduction voltage slopes in a recorded voltage-capacity cycle compared to a previous cycle with those features which indicate progression of development of the SEI;
observation of unchanging features/stability in features in the recorded charge-discharge cycle under comparison of differences between a particular formation cycle and the preceding or subsequent formation cycle;
absence of ‘low voltage’ features (e.g., below about 1.5V after initial cycles for the exemplified half cell) in the recorded charge-discharge cycle under comparison of differences between a particular formation cycle and the preceding or subsequent formation cycle. The low voltage features will be known/determinable to the person skilled in the art as being associated with electrolyte reduction/decomposition and/or electrolyte additive reduction/decomposition. Such features may be determinable by separate electrochemical studies carried out on the particular electrolyte system used, e.g., by CV studies or the like which are capable of identifying oxidation reduction peak voltages for the ionic liquid (cation and/or anion) and the anion of the metal salt used, or any additives included;
observation that the cell's cut off discharge potential limit is reached without presence/appearance of curve features associated with sodium ion insertion into the negative active electrode, that is, intercalation features, e.g., in the described half-cell examples, sodium ion insertion is identified by presence of a flat plateau at around 0.01V (that is absence of insertion peaks in the curves during the formation cycles where by the insertion peaks are found in cycles once the improved SEI formed is substantially completed and substantially stable); and
observation of minimal or stable irreversible capacity loss between cycles;

### (b) Electrochemical Impedance Spectroscopy (EIS) Markers/Features

evidence of a low and/or stable EIS span in electrochemical impedance studies e.g., involving recorded Nyquist plot analysis. For example, for an unstable SEI, the EIS will show significant increase in impedance and/or decay into noise due to the lack of stability. A stable SEI would not reflect this behaviour;
evidence of formation of a low impedance SEI, e.g., arising from EIS magnitude and amount of polarisation under load, that is the drop or increase in relative potential under load for full cell or symmetric cell under equivalent conditions (current, temperature, etc);
evidence of a more highly ionically conductive SEI than that of a formed test cell. For example, in the provided half-cell studies, Ohm values ranging in the 10s to 100s indicates good transfer of Na ion through the SEI and electrode interface.

### (c) Differential Capacity Analysis Markers/Features

absence of electrolyte reduction/decomposition and/or electrolyte additive reduction/decomposition peaks in a recorded differential capacity curve (dQ/dV). For example, the absence of FSI-anion reduction peaks in the dQ/dV signifies complete formation of the SEI layer in the half cell examples describe herein in the super concentrated IL comprising metal FSI salt;
absence of a metal ion insertion peak indicates complete discharge occurs prior to metal ion insertion;
presence of peaks for adsorption of Na⁺ ions ad/chemisorption onto active sites of the hard carbon electrode at the higher rates instead of a Na⁺ insertion peak before full charge capacity is reached for high rate cells; and
absence of insertion peaks whereby after sufficient SEI formation the insertion peaks become visible.

A detectable difference in capacity for the sodium ion absorption step compared to the desorption step displays the charge which was consumed in SEI formation during any particular polarisation cycle. As formation cycling proceeds, the SEI develops in terms of properties such as composition, ionic conductivity, thickness, porosity, density depending on the cell chemistry and electrolyte used. Development of the SEI is usually considered to be complete several formation cycles (e.g. ⅔ cycles) carried out at conventionally slow charge/discharge rates ( 1/10C or less, 1/20C or less) involving allowing the cell to fully charge and fully discharge which has been thought to be essential for later best performance of the cell. Therefore, less charge consumption as cycles proceed is indicative of the degree of completeness of SEI formation for any given cycle. As SEI formation progresses, the charge lost (irreversible capacity loss) going from one formation cycle to the next reduces as the SEI becomes more complete and more stable and less additional electrolyte is consumed. Once the SEI formed is substantially complete and stable, that is, optimum SEI formation has occurred, the charge lost between the charge and discharge step in consecutive polarisation cycles is minimised given little additional electrolyte decomposition occurs at this stage. Thus, observation of a reduction in the irreversible capacity loss between neighbouring cycles and/or minimal charge lost between the charge and discharge step) can also be used to identify a cycle after which there is substantially complete and substantially stable SEI formation.

During the first formation cycle carried out on the test fresh cell, the method uses a current density low enough so as to achieve a full discharge capacity for the cell in a period of at least 10 hours for a single discharge, more preferably at least 20 hours for a single discharge. This means that formation for the test fresh cell will be slow enough that the SEI formation is slow and the cycle progresses naturally for enough time that ensures that the SEI formed will be substantially complete.

Thus analysis of the test fresh cell may identify the presence and/or absence of electrochemical analysis parameters/one or more markers that are associated with substantially complete and substantially stable SEI formation for the slow formation step.

“Fresh cells” are manufactured cells that have not yet been polarised and thus comprises pristine electrodes. The reference to one or more fresh cells referenced in various steps of the methods described herein, means a fresh unpolarised cell is used, and that cell is from the same batch of cells that is has the same type of chemistry, amounts of active material, type of electrolyte etc. within experimental and manufacture control limits.

For the first formation cycle carried out on the subject fresh cell, the current density is chosen to be higher than that used for the test cell so as to achieve the cell's cut off discharge potential limit and resulting discharge capacity for the subject cell in a period of less than 5 hours for a single discharge, less than 2 hours for a single discharge, preferably 1 hour or less for a single discharge, more preferably 30 minutes or less for a single discharge. The higher current density chosen will result in the cut off discharge potential limit of the fresh subject cell being reached at a faster time than that for the same step on the test cell. For example, the higher current density used mean the cut off discharge potential limit may be reached before sodium ion intercalation has occurred at the hard carbon electrode. Thus, a preferred current density for the subject cell is one resulting in cut off at a low discharge capacity. As such, the subject cell will exhibit a reduced discharge capacity compared to the test cell.

In another aspect, the invention relates to the use of a super-concentrated ionic liquid electrolyte in a cell in a formation method of forming an improved SEI on a hard carbon negative electrode, preferably a hard carbon negative electrode in a sodium ion electrochemical cell in 10 hours or less. The features of the method and the super-concentrated ionic liquid electrolyte are described above. Preferably, the use is use a super-concentrated electrolyte comprising an ionic liquid and at least one sodium salt, wherein the sodium ion concentration is 75% or greater of its saturation limit in the electrolyte, in a formation method for an sodium ion electrochemical cell comprising a hard carbon working electrode, preferably a hard carbon working electrode, wherein cell formation is complete in 10 hours or less at 50° C. Suitably, the use involves a cell where the sodium ion is sodium ion and the hard carbon working electrode is hard carbon and the electrolyte is [C₃mpyr][FSI]IL with about 50 mol % NaFSI salt. About in this case means±2%.

### Definitions

“Electrochemical cell” means a device capable of converting chemical potential energy into electrical energy.

“Half-cell” means the cell is in a half-cell configuration whereby the cell comprises a working electrode under study and a counter electrode, and is controlled by potential. In the half-cell configuration, electrical charge can only be extracted during discharge to a negative cell voltage. When in a half-cell configuration, the cell of the invention may be suitable for use as a diagnostic or test device which can assist with measuring the electrochemical characteristics of the electrolyte, or identifying suitable positive electrodes for use in a full cell configuration according to the invention.

“Full cell” means the cell is in a full cell configuration, controlled by cell voltage, such as a battery. In such configurations, the cell further comprises a positive electrode material as the counter electrode and a negative electrode material as the working electrode. As used herein, the expression “full-cell configuration” refers to a cell configuration in which the positive and negative electrode support a substantial potential difference (e.g., greater than about 1 V) after charging and from which electrical charge can be extracted during discharge at a positive cell voltage. Where the electrode couple is a suitable pair of negative and positive active material electrodes, the cell is a full-cell configuration. Where the electrode couple supports high current density at the negative electrode and sustains a high number of polarisation or charge/discharge cycles, the couple is suitable for use in a cell which can serve as a high capacity and cycle-stable metal ion based rechargeable battery.

“Intercalation” means the reversible insertion of transport metal ions into the atomic structure of an electrode.

“Negative electrode” refers to the electrode at which electrons leave the cell during discharge (anode during discharge; cathode during charge). For example, when in electrical contact with the sodium ion ionic liquid electrolyte used according to the invention, the negative electrode material gives rise to (i) the formation of a SEI layer as a result of the having undergone at least one polarisation cycle, where electrolyte reduction at the electrode forms the SEO. The negative electrode may comprise (or be made of) hard carbon materials that can reversibly intercalate sodium ions within their atomic structure, interact with sodium ions (e.g. absorption/desorption) by promoting reversible oxidation/reduction reactions, or promote alloying/dealloying reactions with sodium ions. Examples of material which the hard carbon negative electrode may comprise (or be made of) include: hard carbon, graphite, activated hollow carbon, expanded graphite, hard carbon composites, and doped analogues thereof.

“Positive electrode” refers to the electrode at which electrons enter the cell during discharge (cathode, during discharge; anode during charge). For example, a positive electrode may comprise (or be made of) material that can reversibly intercalate sodium ions within their atomic structure, absorb/desorb sodium ions by reversible oxidation/reduction reactions, or promote alloying/dealloying reactions with sodium as described herein.

“Sodium ion ionic liquid electrolyte” refers to an ionic liquid obtained by dissolving an sodium salt into an organic salt. In some embodiments, the sodium salt is the sodium salt equivalent of the organic salt (i.e., they share the same anion).

A “polarisation cycle” means a cycle of charging and discharging the cell. A “formation cycle” means the initial cycle or initial few (up to first 5) polarisation cycles within the cell's lifetime that promotes formation of the SEI layer on the working electrode, negative electrode material or “anode”. By the cell having undergone a “polarisation cycle” is intended to mean the cell has been subjected to a two-step cycle comprising: a step in which electric current of a certain density flows through the negative electrode along one direction; and a step in which the electric current is switched to flow through the negative electrode along the opposite direction. In some embodiments, the cell according to the invention may be configured and used such that electric current flows through the negative electrode along opposite directions in a cyclical manner. That is, the cell may be subjected to multiple polarisation cycles in which electric current flows through the negative electrode along alternating opposite directions. As a result, an electric potential of alternating sign can be observed.

A skilled person will know the technical meaning of the expression “charge/discharge cycle”, and how to perform such procedure. For example, a charge/discharge cycle may be the charge/discharge performed to activate a rechargeable battery following assembly. As a skilled person would know, this refers to the procedure adopted to form a negative electrode by way of charging/discharging routines under controlled voltage, temperature, and environmental conditions, which is performed with the intention of inducing formation of the solid-electrolyte interphase (SEI) layer at the negative electrode. For avoidance of doubt, in the context of the present invention it will be understood that a polarisation cycle is equivalent to one charge/discharge cycle.

“Coulombic efficiency (CE)” is defined as the quotient of the discharge capacity and its antecedent charge capacity for a given set of operating conditions. It is a measure of how reversible the electrochemical energy storing reactions are, with any value less than unity indicating non-productive, often irreversible reactions. Any reduction in CE from unit reflects a number of non-productive reactions in every 1000 reactions which will result in irreversible losses of reactants in each cycle that compound to great consequence over hundreds of cycles.

“Irreversible capacity” is defined as the amount of charge lost between the discharge capacity and its antecedent charge capacity for a given set of operating conditions and reflects the magnitude of the irreversible processes occurring during a polarisation cycle.

“Cumulative irreversible capacity” is defined as the cumulative sum of the irreversible capacity across multiple polarisation cycles and reflects the progression of irreversible processes in the cell.

### Description of Preferred Embodiments

The present invention is described with reference to the following examples. It is to be understood that the examples are illustrative of and not limiting to the invention described herein.

The general principal of application behind the present invention is demonstrated by the following half-cell studies involving high current density polarisations (for up to 5 formation cycles) of a pristine cell comprising a sodium metal counter electrode and a hard carbon working electrode in super-concentrated IL which is a 1:1 IL:Na salt which is C₃mpyrFSI IL with 50 mol % NaFSI salt. The SEI formed has the desired compositional features described in the present disclosure.

### Materials and Methods

### Electrolyte Preparation and Slurry Casting

Hard carbon (HC) was purchased from Kuraray company (Kuranode, SSA=4 m²/g). Na metal was bought from Sigma-Aldrich. Battery-grade sodium bis(fluorosulfonyl)imide (NaFSI, 99.7%) and N-methyl-N-propylpyrrolidinium bis(fluorosulfonyl)imide (C3mpyrFSI, 99.9%) were purchased from Boron Molecular. Dimethyl carbonate (DMC, 99%) was purchased from Sigma-Aldrich and is used to wash the cycled electrodes. The electrolytes were dried under vacuum by Schlenk line at 50° C. before use. The superconcentrated ionic liquid was prepared by dissolving 50 mol % NaFSI into C₃mpyrFSI, with stirring at 50-C for 24 h, prior being transferred into the glovebox. The HC anode was prepared by mixing hard carbon, carboxymethyl cellulose (CMC, Sigma-Aldrich) and carbon black (Sigma-Aldrich) with water as solvent at a ratio of 8:1:1. The slurry was then coated on the Al current collector using the doctor blade. The mass loading of the HC electrode is 1 mg/cm².

### Electrochemistry Measurement

Na/HC cells were prepared in the glovebox with O₂ and H₂O levels lower than 0.1 ppm. The R2032 half-cell was assembled with a HC electrode (8 mm diameter) as the working electrode, and Na metal (10 mm in diameter) as the counter and reference electrode. Solupor® polyethylene 5P09B (19 mm in diameter, 38 μm thickness, 86% porosity) was used as the separator. Three-electrode cell was assembled in the same way in a custom-made setup, with two separate Na metals as counter and reference electrodes, respectively. The assembled cells were rested for 24 h at 50-C for wetting prior to testing. The Na/HC cells were cycled using a Neware battery cycler under different C-rates (2 C, 1 C, and 1/10 C, C=300 mAh/g) within the voltage range between 0.01 and 2 V before cycling under the same current density for long term test. EIS measurements were conducted using a Biologic VMP potentiostat with a frequency range from 1 MHz to 100 mHz.

### Material and Electrode Characterizations

Post-mortem characterizations were carried out by X-ray photoelectron spectroscopy (XPS) and solid-state Nuclear Magnetic Resonance spectroscopy (NMR). XPS was performed on a Thermo Scientific Nexsa spectrometer equipped with a hemispherical analyzer. The incident radiation was monochromaticAl Kα X-rays (1486.6 eV) at 72 W (6 mA and 12 kV, 400×800 μm spot). Survey (wide) and high-resolution (narrow) scans were recorded at analyser pass energies of 150 and 50 eV, respectively. Survey scans were performed with a step size of 1.0 eV and a dwell time of 10 ms. High-resolution scans were obtained with a step size of 0.1 eV and dwell time of 50 ms. The base pressure in the analysis chamber was less than 5.0×10⁻⁹ mbar. A low-energy dual-beam (ion and electron) flood gun was used to compensate for surface charging. All data were processed using Casa XPS and the energy calibration was referenced to the low binding energy component of the C 1s peak at 284.8 eV. The etch depth was based on Ta₂O₅(of 0.30481 nm/s) and has been used as an approximation in all depth analyses. Solid-state magic angle spinning (MAS) NMR experiments were collected on a 500 MHz (11.7 T) Bruker Avance III wide-bore spectrometer. The samples, formed under different formation protocols, were scratched from the cycled cathodes in an Ar glovebox. A control sample, soaked in the ILs electrolytes for 24 h, was also prepared by the same procedure. The samples were then rinsed with DMC and dried under vacuum before being mixed with boron nitride as a filler material and then loaded into the 1.3 mm MAS NMR rotor. They were then spun at 40 kHz using dried air. ²³Na spectra were acquired using a single-pulse experiment and a recycle delay of 0.5 s with 20,000 scans acquired. ¹⁹F spectra were acquired using a Hahn echo pulse sequence with a 50 μs echo delay, a 1 s recycle delay and 20,000 scans acquired. Both nuclei were referenced using solid NaF (δ=7.4 ppm for ²³Na and −224.2 ppm for ¹⁹F). All the samples were packed in an argon environment.

### Results & Discussions

### Example 1—Galvanostatic Charge-Discharge SEI Formation—Capacity, Cycling Performance and Coulombic Efficiency

Galvanostatic charge-discharge of a cell (based on measuring the potential in a cell polarized with a constant current) reveals the irreversible capacity loss occurring during SEI formation while further illustrating the SEI stability by a consideration of capacity retention as the cell cycles, e.g., at later nominal C rates for the particular cell.

The initial SEI formation occurring at the hard carbon electrode as a result of the first sodiation process (occurring during first formation cycle for a pristine cell in half cell configuration) is recognisable from the presence of features associated with electrolyte component reduction/decomposition, e.g., a voltage slope during the first charge step in full-cell measurements, but which proceeds in the first hard carbon sodiation step/discharge process in the case of half-cell studies involving a sodium metal counter electrode. A voltage slope associated with electrolyte reduction/decomposition from electrolyte reaction is a useful marker of incomplete SEI formation. The presence of similar electrolyte decomposition/reduction voltage slopes in the subsequent formation cycles indicates that the SEI for a particular cycle is not complete or can provide information that the SEI is nearing completion as the voltage slope shortens over successive sodiation cycles. Similarly, SEI formation/electrolyte reduction peaks can be observed in cyclic voltammetry experiments. Other markers include changes in the EIS during cycling such as significant fluctuation and generation of noise, are also apparent where a SEI is not complete and stabilized. Conversely, a substantially noise free EIS during cycling indicates the formation of a stable and complete SEI. For example, a S/N ratio of 10 or less, preferably 5 or less, most preferably 3 or less, indicates the SEI is stable/complete.

Furthermore, observation of minimal irreversible charge lost between successive charge and discharge step can also be used to identify a cycle that results in substantially complete and substantially stable formation of a SEI.

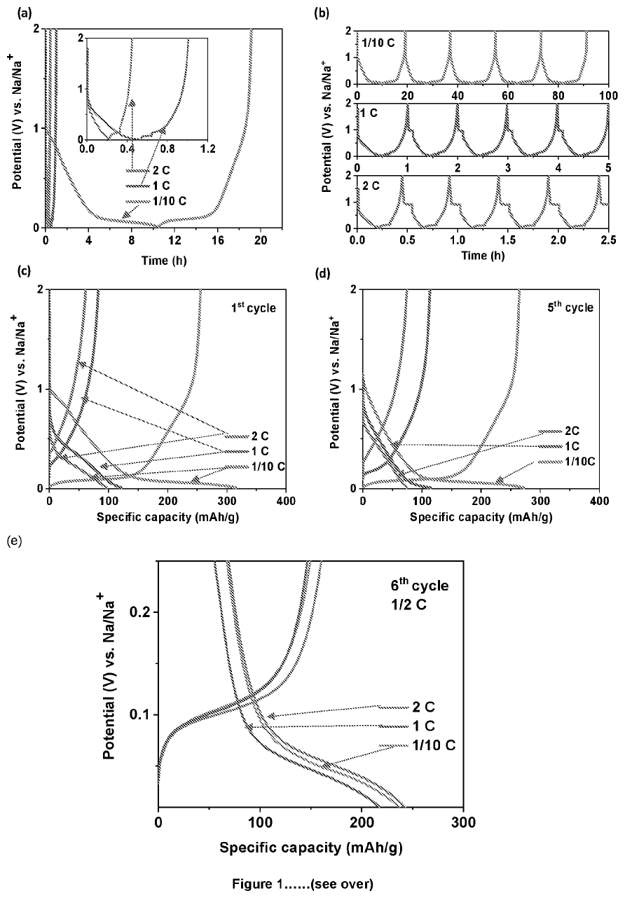

In proof of concept experiments, three different formation protocols ( 1/10C for test cells, 1C or 2C for subject cells) were applied on a hard carbon working electrode in a fresh half-cell set up using sodium metal as counter electrode, within a full voltage window of 0.01 V cut-off voltage for sodiation and 2 V for the de-sodiation process for the half cell chemistry. Various potential vs. time curves for the baseline ( 1/10 C, based on C=300 mAh/g for the HC) and the alternative formation protocols (1 C and 2 C) can be observed in FIG. 1a. In this study, up to five formation cycles were used to observe the progress/establishment of a complete and stable SEI, though in the higher current density processes, complete SEI formation made occur after just the first or second cycle. The traditional formation protocols with conventionally slow 1/10 C current density steps takes around 20 h for one complete formation cycle (so about 10 hours for the discharge step), and in total, about 95 h for the 5 cycles (see FIG. 1b) required for complete and stable SEI establishment in the 1/10 C test cell. By contrast, 1 C and 2 C formation protocols only take about 1 h and about 0.5 h per charge or discharge cycle, respectively, reducing the total formation time for 5 cycles (needed to observe complete and stable SEI establishment at 1/10 C) to an incredibly short 5 h and 2.5 h, respectively for 5 formation cycles for 1 C and 2C cells. In cases where complete SEI formation made occur after just the first or second cycle, this time will be even shorter.

As evidenced the galvanostatic charge/discharge curves of FIG. 1c, for the first formation cycle involves sodiation of hard carbon in the galvanic half-cell, the conventionally slow 1/10 C formation test cell displayed a discharge curve indicating a full discharge capacity of 313 mAh/g occurs at the cut-off sodiation voltage, with a reduction slope starting at around 0.75 V followed by a long flat plateau at around 0.01 V. A reduction plateau between 0.85 V and 0.97 V can be observed at the 1^{st}cycle at 1/10 C (see FIG. 1(f)) which has disappeared at the 5¹ h cycle. The discharging voltage reduction slope of around 0.75 V is attributed to SEI formation on the hard carbon surface (i.e., electrolyte decomposition), whereby the long flat plateau that follows, starting around 0.01 V is attributed to Na⁺ insertion occurring into the hard carbon graphitic layer which contributes to high capacity achieved at the slow C rate (see FIG. 1(c) & (f). The 1/10 C rate mirrors the low current density used in a conventional slow formation rate where achieving full discharge capacity during polarisation is expected to be beneficial for optimum SEI formation. CV cycling (see FIG. 1(g)) indicates a small reduction peak (around 0.73 V) derived from the electrolyte decomposition at the 1^{st}cycle, but which could not be observed at the 5^{th} cycle indicating that SEI formation was mainly complete by the 5^{th} cycle under 1/10 C conditions. The broad reaction peak between 0.2 V and 1 V corresponds to adsorption of Na cluster on the carbon defects.

Interestingly however, the sodiation reaction for the first formation cycle for the 1 C subject cell and the 2 C subject cells is not complete, indicated by short reaction slopes occurring at an onset 0.5 V and 0.35 V, respectively, where the majority of the capacity is dominated by the electrolyte reduction (voltage slope signifying SEI formation) and Na⁺ adsorption to the surface, without the capacity increase for sodium insertion/intercalation during the initial formation cycle which was observed for the 1/10 C cell. Thus, the full discharge specific capacities achieved for the high rate cells are very low at 121 mAh/g for 1 C and 97 mAh/g for 2 C, compared to the 1/10 C cell at 313 mAh/g. Given the poor capacity observed, these cells would not have been expected to produce useful SEIs under these formation conditions.

As the voltage slope for the 2C subject cell is shorter than that of the 1C cell and shorter again than that of the 1/10 C cell, this signifies the least electrolyte decomposition has occurred in SEI formation of the 2C cell, while in both high current density cases, less electrolyte decomposition has occurred during SEI formation compared to same stage for the 1/10 C cell. That is, less electrolyte is used up during SEI formation. The amount of electrolyte lost corresponds to irreversible capacity lost between charge and discharge for successive cycles. Further, the curves for the 5^{th} cycle show very little capacity loss between the charge and discharge curve (see FIG. 1(d)) indicating that by completion of the 5^{th} cycle in all cells, the SEI formed was substantially complete and substantially stable at that stage.

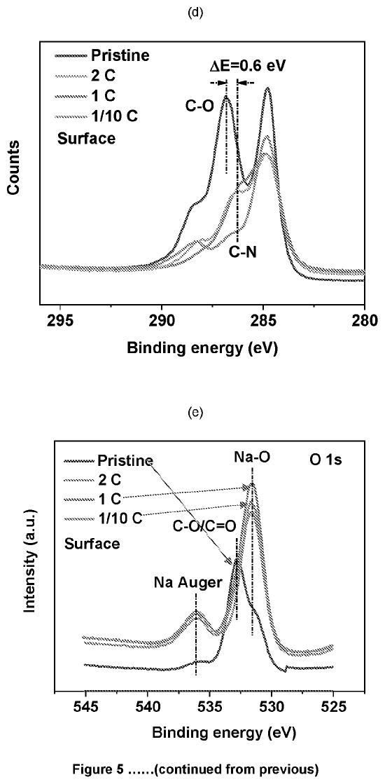

The charge-discharge curves for 6^{th} cycle for the 1/10 C formed test cell, and the 1 C and 2 C formed subject cells are shown in FIG. 7(a) and 7(b) ((b) is an expanded view of a portion of FIG. 7(a)). The curves for the 2C formed subject cell at the 6^{th} formation cycle at the 2C rate shows lower sodiation and desodiation overpotentials for the 2C sample than for the other cells, whereby the potential is less negative during sodiation equating with more facile sodiation and less positive during more facile desodiation compared to the previous (5^{th}) formation cycle, and as compared to the 1C and 1/10C formation cell 6^{th} cycle profiles. This is due to the complete and stable SEI formation which occurred by the 5^{th} formation cycle. It is also interesting the note the presence of the long voltage plateau which is associated with the sodium insertion/intercalation into the hard carbon anode which signifies the cell is accommodating and releasing much more charge during this cycle.

FIG. 1(d) clearly shows the later charge/discharge behaviour of the three formed cells at a nominal C rate of ½ C after completion of the considered formation protocols. Unexpectedly, the 2C formed cell delivered the highest discharge capacity of 242.5 mAh/g, followed by 237.0 mAh/g for 1/10 C cell and 216.8 mAh/g for 1 C cell. This reveals that the SEI formation resulted from the high C-rate is beneficial for sodium storage in terms of surprisingly good capacity storage given the speed of formation and harsh high current density conditions used.

### Example 2—Differential Capacity Analysis

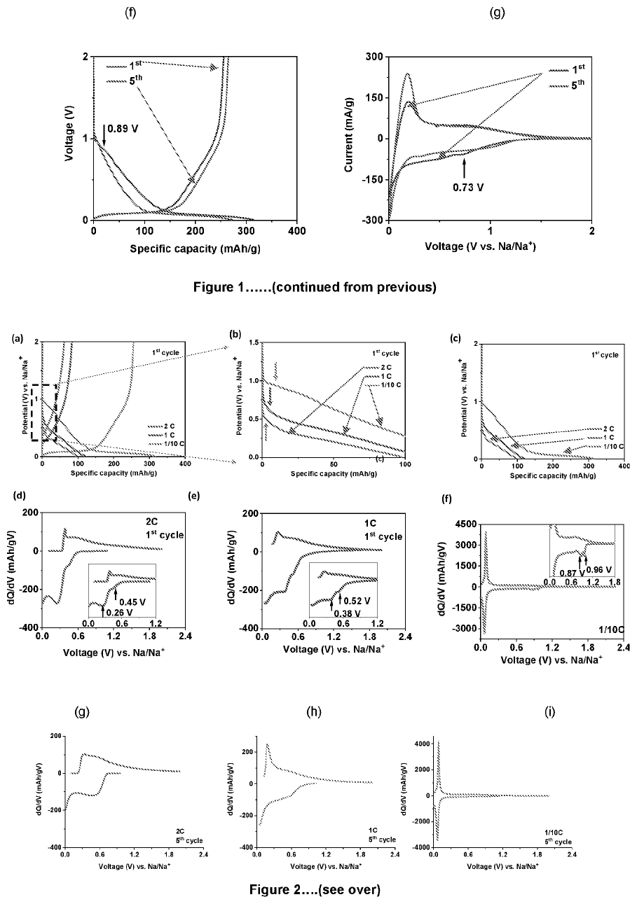

Delta dQ/dV analysis can give a comprehensive understanding on the peak de-convolution involving the formation of the SEI, and Na⁺ intercalation/de-intercalation. As such, SEI formation procedures under different formation C-rates can be distinguished. Two reduction peaks at 0.96 V and 0.87 V are witnessed for the initial cycle in the 1/10 C cell (FIG. 2f), which are assigned to the electrochemical reduction of FSI-anions in the electrolyte due to the different coordination environments. Note that the reduction peaks at the 1^{st} cycle are not detected at the 5^{th} cycle (FIG. 2g-i) for all cells, indicative of establishment of the complete and stable SEI by that stage. When the C rates are increase to 1 C and 2 C, the peak positions shifted to lower (more negative) potentials during the first discharge process with 0.52 V for the 1 C cell and 0.45 V for the 2 C cell, respectively. These changes suggest differences in the SEI formation mechanism due to the interface and mass transport interactions occurring under these conditions.

Interestingly, the peak magnitudes decrease significantly, and the peak shape becomes broader when the current densities increased from 1/10 C to 1 C and 2 C. This can be caused by the large amount of charge approaching to the carbon surface under the low C-rate, of which the majority of the charge goes to the low plateau region (0.01-0.1 V), leading to a full capacity. Whereas the peak intensity is limited by Na⁺ ion transport at higher rates associated with the concentration gradients, leading to shorter relaxation time for the phase equilibrium, and resulting in an inhomogeneous Na distribution near the carbon surface. Consequently, the inhomogeneous sodium distribution across the hard carbon surface leads to higher overpotential and broader redox peaks. Meanwhile, the electrolyte decomposition process to form the SEI layer and the corresponding SEI configurations are affected as well, which will be discussed in the following part. As the reduction peaks at the 1st cycle are not detected at the following cycles (FIG. 2(d)-(i), FIG. 2(j)-(q), this is indicative of the established SEI formation in the first cycle. The two large peaks at 0.6 V in FIG. 2(g)-(h) are attributed to the ad/chemisorption of Na⁺ ions onto the active sites of the carbon material, which is different from the insertion peak in FIG. 2(i) where the majority of capacity is from the diffusion contribution.

### Example 3—Coulombic Efficiency

All the formed cells with complete and stable SEI formation (after 5 cycles) were then cycled at a same selected nominal C rate for the cells (½ C and ⅕ C) for further evaluation after completion of the 5 formation cycles.

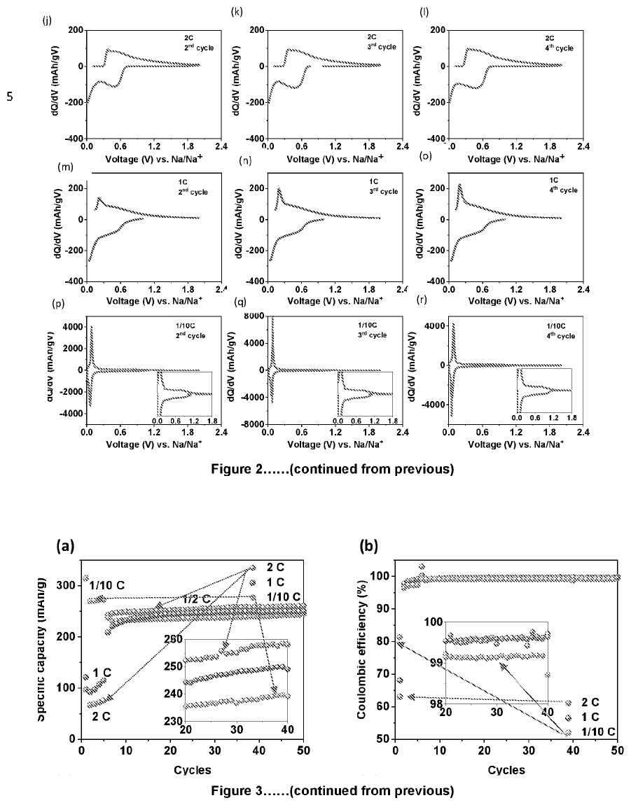

On such cycling, the formed cells exhibited distinct capacity variation at ½ C (FIG. 3(a),(c),(d) & (g) and the specific capacities at the 40^{th} cycle are 258 mAh/g for 2 C, 250 mAh/g for 1 C and 240 mAh/g for 1/10 C, respectively (see FIG. 3(b)). It is noted that the incremental capacity trends for all Na/HC cells at ½ C current density thought to probably be due to the wettability of highly concentrated electrolytes into hard carbon materials under high C-rates, which is related to the concentration gradients. The long-term charge capacity of the three cells in FIG. 3 follows the same trend where the 2 C cell has the highest charge capacity and the 1/10 C cell has the lowest value. The Coulombic efficiency (CE) in FIGS. 3(b) & (h) for the three cells are in agreement with the cycling data, where the 1/10 C cell shows the lowest CE averaging 99.0% during cycling, whereas the 1 C and 2 C cells are higher and are both close to 99.6%. This is probably related to the SEI reconstruction from 1/10 C formation that will cause more irreversible electrochemical byproducts to be formed. The lower CE for the 1/10 C cell will to some extent lead to faster capacity fading and has a detrimental effect on the full cell performance.

The superior CE of 99.6% for the 1 C and 2C formed subject cells is thought to be related to formation of a robust, substantially complete, and substantially stable SEI layer on the carbon surface by the 5^{th} formation cycle under the high C-rate which is broadly homogenous and is more ionically conductive than that of the 1/10 C test cell, and thus promotes diffusion of Na⁺ across the SEI. The stability of the SEI after 5 cycles can also be observed from EIS studies.

FIG. 2b is the inset picture from FIG. 2a, where electrolyte decomposition is occurring during the first cycle during which the SEI is initially formed. The three arrows in (b) point out the reduction plateaus which are very small and difficult to view in these curves. Therefore, this feature may be more clearly evidenced by consideration of the corresponding dQ/dV curves of FIG. 2d-e) which are in consistent with the reduction peaks from inset pictures in FIGS. 2d-f (at 0.45 V, 0.52 V and 0.96V respectively), which clearly indicated the electrolyte decomposition peaks.

Further, FIG. 2c shows the Na⁺ insertion plateau at around 0.01 V for 1/10C test cell, while 1C and 2C subject cells do not show the same insertion plateaus. This is because the high current used leads to large polarization associated with the Ohmic resistance, and thus it takes less time for the cell to reach to the cut-off potential than the 1/10C cell, and so the insertion reaction is not complete. This is the reason the 1C and 2C subject cells have much lower capacity than 1/10C cell during the formation cycles. The SEI formation is indicated at the region between 1 V-0.5 V as it is through that region SEI is formed. Notably, the capacity observed in the five formation cycles does not affect the capacity in the long term as can be seen from FIGS. 3a and b. Instead 2C has better capacity because of the SEI formed at the region between 1 V-0.5 V is more complete and more ionically conductive, which enhances the Na⁺ reaction kinetics.

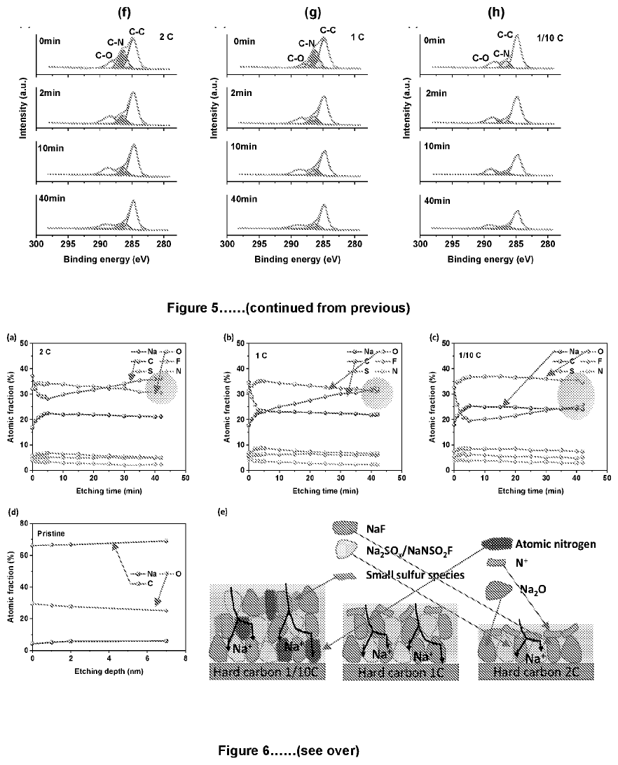

Cumulative irreversible capacities of three cells are summarized in FIG. 3e. 1/10 C cell has the highest irreversible capacity of 59 mAh/g for the initial cycle, compared with the 1 C cell of 38 mAh/g and 2 C cell of 36 mAh/g, signifying less electrolyte consumption for the faster rate cells. This is confirmed by the reduction plateau at 0.75 V for 1/10 C cell, which is associated with large amount of electrolyte decomposition. High cumulative irreversible capacities for 1/10 C cell can be observed for the continuous formation cycles (insert picture in FIG. 3e), whereas the values for the three cells become negligible when the current densities are changed to ½ C. FIG. 3(f) demonstrates the cycling stability for 2 C formation cell under the current density of ½ C over 300 cycles. The cell shows a highly reversible capacity of 259 mAh/g after 300 cycles with a capacity retention of 99.7%. The charge/discharge curves at 50^{th} cycle and 300^{th} cycle in FIG. 3(i) implies the negligible capacity difference between the two cycles, which is in good agreement with the stable cycling performance. The influence of the fast formation protocols on the rate capability test can also been found in FIG. 8(c), (d), where the 2 C cell has higher specific capacity of 260 mAh/g when the current density was decreased from 2 C to 1/10 C. The 2 C formation cell keeps the advantages over the 1/10 C cell at the low current densities, with an average capacity increment of 8 mAh/g and 6 mAh/g at ⅕ C and ½ C, respectively. However, when the ⅕ C current density is applied (FIG. 3g), all cells show a considerably higher capacity of 280±2 mAh/g, whereas the charge capacity in FIG. 3d has the relatively lower value of 275±2 mAh/g due to the irreversible Na⁺ intercalation. Meanwhile, the CEs display the similar values of 98.5±0.2% in FIG. 3h, indicating that the cell performance is not diminished by the fast formation C-rates. Higher C rates of 3 C and 10 C were also examined on the Na/HC cell (FIG. 3(j) in order to compare with the 2 C formation. When the current density changed to ½ C, the 10 C cell slowly recovered with the capacity increasing from 77.8 mAh/g to 216.7 mAh/g from 6^{th} cycle to 50^{th} cycle. Interestingly, the capacities of 2 C and 3 C cells quickly increased to 260 mAh/g and 250 mAh/g at 20^{th} cycle, respectively. This can be explained by the unfavourable SEI generated from 10 C formation on the carbon surface, which does not facilitate the Na⁺ diffusion and hence the capacity is lower than 2 C formation cell. The inset picture indicates there is an average capacity increment of 6 mAh/g from 3 C to 2 C cell between 20^{th}-40^{th} cycles. Here, under the current conditions, the inventors concluded that the 2 C pre-treatment is the optimized formation protocol in the HC sodium ion half-cell when highly concentrated ionic liquid electrolytes are used. Clearly the optimized formation protocols described herein do not restrict the cell performance, and unexpectedly instead the cells after fast C-rates show better performance than the conventional formation cells under a certain current density, and the formation times for Na/HC in super concentrated ionic liquid electrolytes can be decreased by a factor of 38×.

### Example 4-Electrochemical Impedance Spectroscopy

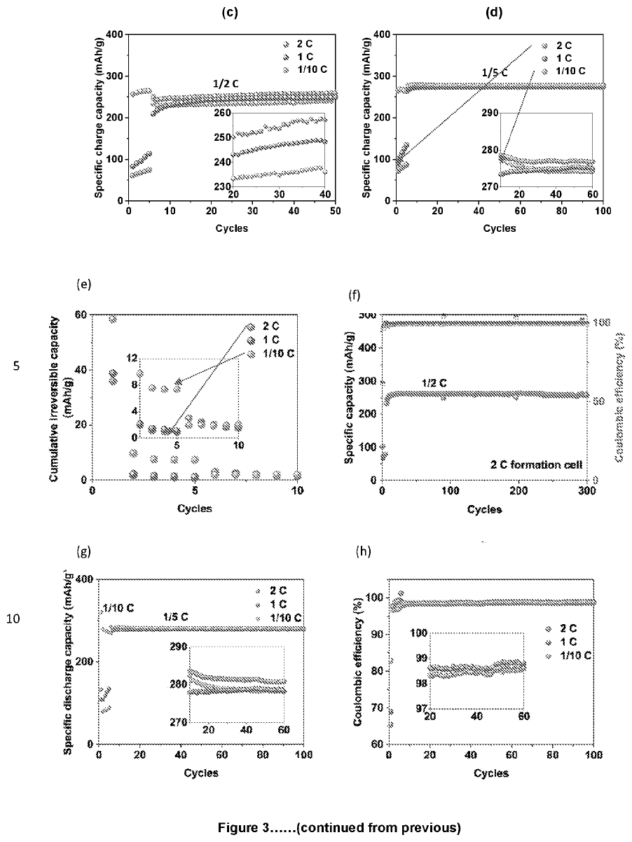

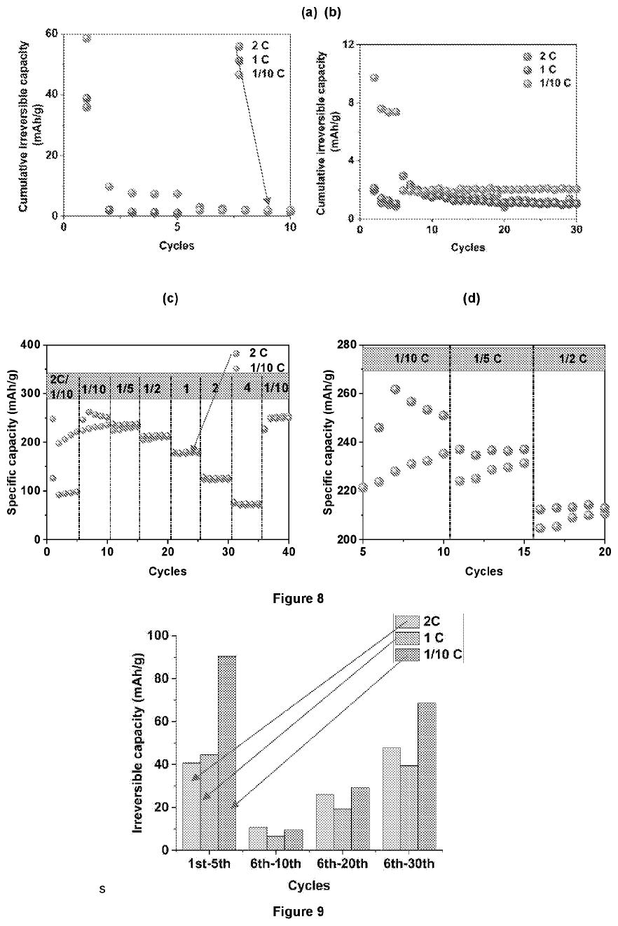

In order to correlate the formation protocols with the interfacial properties on the carbon surface, EIS (Electrochemical Impedance Spectroscopy) measurements were conducted. A three-electrode setup was designed with one Na foil as a counter electrode, one Na roll as a reference electrode, and hard carbon as the working electrode. Thus Na metal act as both reference electrode and counter electrode in the EIS experiment. The aim of the three-electrode EIS measurement is to exclude the contribution from the Na counter electrode on the interfacial properties. Nyquist plots in FIG. 4(a)-(c) indicate various EIS resistance of three formation cells after 1st, 2nd and 5^{th} cycles, and it clearly shows the lowest resistance for the 2 C cell, while the 1/10 C cell has the highest value. The curves are further fitted into three components using an equivalent circuit and the results are shown in FIG. 4(d)-(f), Table 1, and FIG. 10. Preferred SEI/HC electrodes have a Rᵢₙₜ of less 500 Ohms, preferably 300 Ohms or less, more preferably 200 Ohms or less after a first formation cycle, a second formation cycle, a third formation cycle, a fourth formation cycle or a fifth formation cycle. Particularly preferred SEI/HC electrodes have a Rᵢₙₜ of 100 Ohms or less, more preferably 75 Ohms or less after a first formation cycle, a second formation cycle, a third formation cycle, a fourth formation cycle or a fifth formation cycle. In some cases, after more than 1 formation cycles at, for example, 2 C, the Rᵢₙₜ can be less than 50 Ohms. The Rᵢₙₜ can be determined by EIS set up as described above.

TABLE 1
Summary of fitted EIS data for 3 formation cells at 1st, 2nd and 5th cycles

| | | R_{Ohm} | Rᵢₙₜ | R_{ct} |
|---|---|---|---|---|
| 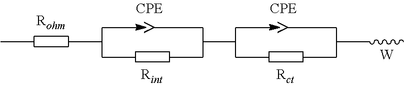 | Cycles | Ohmic resistance of the whole battery including electrolyte current collector etc. | Interfacial resistance associated with SEI layers | Charge transfer resistance across the SEI and electrode |
| 2 C cell | 1st | 24.8 | 57.3 | 6.1 |
| | 2nd | 21.3 | 37.5 | 17.5 |
| | 5th | 21.2 | 42.4 | 12.5 |
| 1 C cell | 1st | 24.4 | 185.5 | 101.3 |
| | 2nd | 24.4 | 145.3 | 116.8 |
| | 5th | 24.0 | 161.4 | 54.1 |
| 1/10 cell | 1st | 41.8 | 593 | 49.2 |
| | 2nd | 48.9 | 574 | 11.8 |
| | 5th | 49 | 506 | 69 |

The Ohmic resistance is from the whole battery including electrolytes and current collectors. The semicircle at the high frequency region is assigned to the interfacial resistance where the Na⁺ diffuses across the SEI layer. The medium-frequency semicircle is the charge transfer resistance which is due to the Na⁺ diffusion into the HC bulk.

The 2C formation cell showed the smallest resistance at 45 Ohm, while the 1C formation cell has a resistance of 300 Ohm, while the 1/10C formation cell showed the highest resistance of 700 Ohm. The 2 C cell shows a stable trend in both the interfacial resistance and the charge transfer resistance during the five formation cycles. The interfacial resistances from the 2 C cell (optimized formation protocol) are significantly smaller than that of the 1/10 C cell, indicative of the robust and high ionically conductive SEI formation under the 2 C condition. This could be explained by occurrence of complete electrolyte decomposition and SEI formation for the 1/10C formation cell after the first cycle, whereby a thick SEI layer is formed which results in a long Na⁺ diffusion pathway explaining the higher resistance observed. In contrast, the SEI formation process for 2C formation cell is very fast, hence a different composition of SEI layer with more ionic conductivity is achieved. The SEI in the 2 C cell is beneficial to the Na⁺ diffusion across the electrode/electrolyte interface, and will reduce the activation energy. By contrast, the decrease in interfacial resistance for the 1/10 C cell in FIG. 4(f) after 5 cycles accounts for the incomplete SEI formation and greater electrolyte consumption under the conventional formation process, and is responsible for the sluggish Na⁺ diffusion kinetics.

### Example 5—XPS and Etching Studies

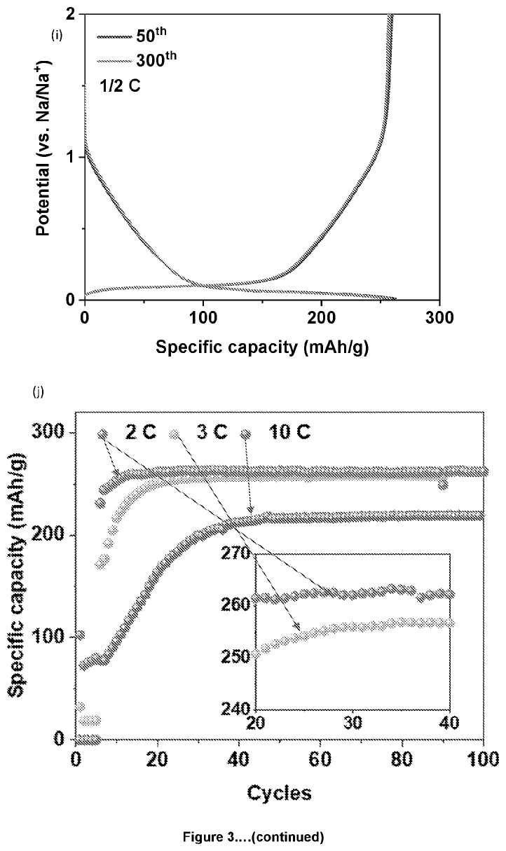

XPS tests were conducted to analyse the SEI composition formed on the HC anodes under different formation protocols. C1s spectra in FIG. 5a and FIG. 5d indicate that the three HC electrodes are all covered by C-N(402 eV) and C═O (288.3 eV) species from the decomposed ionic liquids; whereas a smaller amount of C-N species is found for the 1/10 C cell compared with the 1 C and 2 C cells (FIG. 5(f)-(h)). The C-N peak disappeared after 2 min etching, which indicates that the C-N containing species of the SEI are located on the outer layer. Interestingly, the C-N peak is barely observed for 1/10C formation electrode.

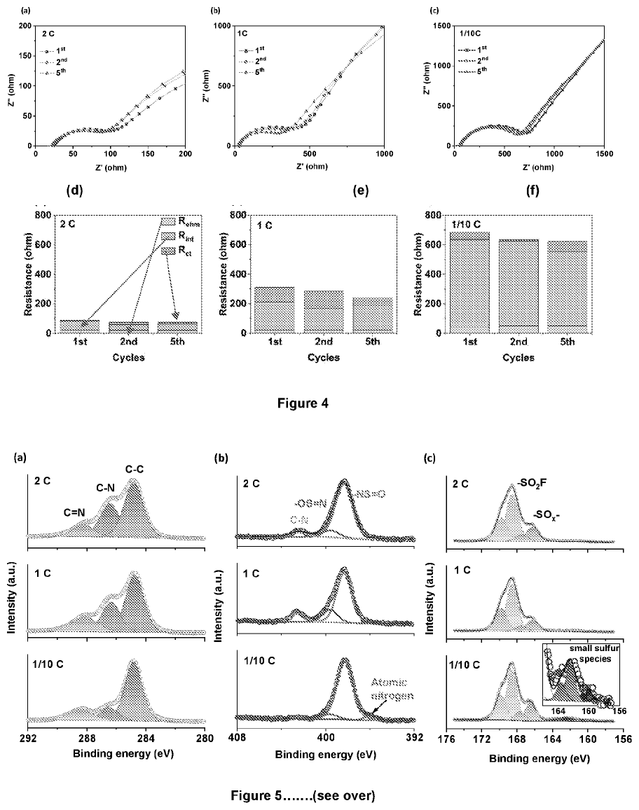

The N 1s spectra in FIG. 5(b) are consistent with the C 1s spectra, explaining the existence of N⁺ (402.8 eV) from the C₃mpyr⁺ is in the outer layer of the SE, which can be removed after Ar⁺ etching (FIG. 6(f) and 6(g)). Apart from the C₃mpyr*, there are two main peaks corresponding to the NS═O (398 eV) and N═SO (399.8 eV) found in the SEI layer, which are derived from the FSI-decomposition. Interestingly, there is an extra peak at 396 eV observed in 1/10 C cell, attributed to atomic nitrogen and which is still obtained even after 40 min of Ar⁺ cluster etching. The atomic nitrogen exists through the entire SEI layer as can be detected from the etching profile in FIG. 6(f). The S 2p high-resolution spectra in FIG. 5(c) indicate the presence of —SO₂F— (168.6 eV) and —SOₓ— (166.3 eV) for all three systems, the ‘small’ sulfur-containing species (inset picture in FIG. 5 (c)) below at 164 eV (164-160 eV) distinguish the 1/10 C hard carbon from its 1 C and 2 C counterparts. Another inorganic SEI composition for all three cells is Na₂0 as can be observed in FIG. 5(e). Although these inorganic species are reported to possess a lower diffusion energy barrier for Na⁺ thereby boosting Na migration kinetics, presence of more reduced sulfur species in the SEI of the 1/10C formation cell made the SEI layer thicker, thereby increasing the Na⁺ diffusion pathway and lowering the reaction kinetics compared with their counterparts.

The etching depth profiles in FIG. 6(a)-(d) give us a clear understanding of the SEI compositions derived from the three different formation protocols considered. The amounts of sulfur (S), fluorine (F), oxygen (O) and nitrogen (N) showed continually increased over the first 6 minutes of etching, while the carbon shows a significant decrease for all three systems. This is due to the fact that the inorganic species including Na₂O, Na₂SOₓ/NaNSO₂F, NaF, etc, exist in the outer layer of the SEI. Notably, the ratio of C and O after 40 min etching is over 1 for 2C formation HC electrode (FIG. 6(a)), which is the same trend as the pristine electrode (FIG. 6(d)), indicative that the surface of the 2 C hard carbon is getting close to the bulk surface after 40-min etching. By contrast, the ratio of C/O for the 1/10 C electrode is less than 1, which is a sign that more Na₂0 species exist in the inner layer of SEI, and therefore contribute to a thicker SEI layer. The C/O ratio for the 1 C hard carbon (FIG. 6(b)) is between the 2 C and 1/10 C cells, following the same trend where the SEI thickness plays a significant role on the capacity and EIS resistance. The schematic illustration in FIG. 6(e) demonstrates the difference in SEI compositions from the three formation treatments: a thin SEI layer is rapidly formed on the hard carbon surface during the 2 C formation, with a shorter Na⁺ diffusion pathway and higher ionic conductivity. Conversely, the 1/10 C cell experienced more extensive electrolyte decomposition, with more inorganic species and minor sulfur and atomic nitrogen elements developed among the SEI compositions, and hence the SEI is much thicker than in the 1 C and 2 C cells, thereby hindering the Na⁺ diffusion into the carbon interlayer, with less ionic conductivity.

Previous work from the inventors indicated that the influence of the SEI formation varies from electrolyte polarity, electrolyte concentration to pre-treatment protocols in both Li and Na batteries. In particular, the MD simulation results concluded that a higher concentration of NaₓFSI_{y} aggregates constructed in the inner layer of the anode under a high rate pre-treatment, forming a favourable inorganic-rich SEI for cell cycling. While with the low rate counterpart, the electrode surface has less concentration of NaₓFSI_{y} aggregates but a significant number of C₃mpyr⁺ cations. The involvement of the C₃mpyr⁺ cation decomposition gives rise to a thick and organic-dominant SEI layer.

The ratio of C/O on 2C hard carbon is in consistent with that of the pristine electrode (FIG. 6d), indicating the etched surface on the 2C formation cell hard carbon is getting close to the bulk surface. However, the opposite C/O ratio for 1/10C formation cell electrode (greater than 1) has a thicker SEI layer, and it is suggested this is the reason why the 40-min Ar⁺ etching has not reached the bottom of the SEI.

The C/O ratio for the 1C formation cell hard carbon (FIG. 6b) is between 2C and 1/10C cell, following the capacity and EIS resistance trends discussed above.

It can be concluded that under high current formation treatment, a thin or otherwise more ionically conductive SEI layer gradually forms on the carbon surface, wherein the SEI has a shorter Na⁺ diffusion pathway and more ionically conductive features. The shorter Na⁺ diffusion pathway could be as a result of a thinner, or a more porous or a less dense SEI, or a combination of one or more of these factors which overall result in a shorter ion diffusion path. This was a surprising finding as conventional thinking for SEI formation from organic electrolytes dictates that a thick and comprehensive SEI layer is required to ensure optimal battery performance. The present results are in complete contrast, given formation using super concentrated ionic liquid electrolyte at high current rates and fast formation time produces a better SEI that has improved ionic conductivity/shorter ion diffusion pathway (thinner, or less dense, or more porous, or all of these properties, etc.) that facilitate improved the battery performance while using up less electrolyte in SEI formation.

The XPS studies support that the 1/10C cell experiences a thorough electrolyte decomposition (consistent with the cycle markers that show more irreversible capacity loss for the SEI formation in the 1/10C cell), with more sulfur and atomic nitrogen elements being developed amongst the SEI component, and hence the SEI is thought to be much thicker, less porous or more dense than the SEIs of the more ionically conductive SEIs of the 1C and 2C formation cells. The SEI from the 1/10C hinders Na⁺ diffusion into the carbon graphitic layers, as a result of its less ionically conductive features. Further as mentioned earlier, the greater degree of electrolyte decomposition occurring during the formation of the 1/10 C cell will eventually lead to a faster capacity decay in the long term due to the resultant electrolyte shortage.

### Example 6—Cumulative Irreversible Capacity Versus Cycle Number

FIG. 8(a) is a plot of irreversible capacity (mAh/g) versus cycle number for the 1/10 C test cell and the 1C and 2C subject cells for the first 1 to 10^{th} polarisation cycles including the first 5 formation cycles. The irreversible capacity data shows there is much less irreversible capacity loss in the 1C and 2 C formations cells (1^{st} to 5^{th} cycles), while thereafter (for the 6^{th} to 10^{th} cycles) after formation of the necessary substantially complete and stable SEI, further irreversible capacity loss is very low and very similar for each cell in the 6^{th} to 10^{th} cycle). This data indicates that for the cells formed according to the formation method of the invention, there is less charge going into SEI formation during each formation cycle, than the corresponding cycle for the test cell formed using a current density that is in line with conventional low current densities used in commercial formation protocols. The fact that less charge is diverted to the SEI formation signifies that the SEI formed for the subject cells in cycles 1 to 5 is different and/or improved compared to that of the test cell. It is believed that the differences/improvement may be one of more of: a more ionically conductive SEI (with respect to sodium ion transport); or a thinner SEI, which is more ionically conductive and/or porous and/or less dense and/or has lower impedance and/or has greater stability; or a similar thickness SE, which is more ionically conductive and/or porous and/or less dense and/or has lower impedance and/or has greater stability, or a combination of one or more of these factors which overall result in a shorter ion diffusion path. Further key features of the SEI formed by the formation process proposed by the invention is the subsequent stability of the SEI (after the necessary formation cycles are complete) in maintaining low impedance, as well as sustained charge transfer during later cycling at nominal C rates for the cell.

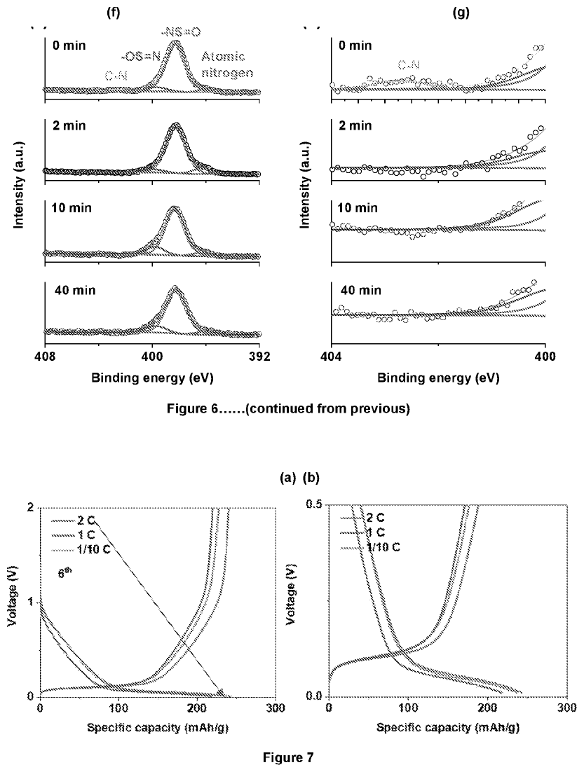

FIG. 9 shows the accumulative irreversible capacity from the first 5 formation cycles which indicates that the 1/10C formation test cell has the largest irreversible capacity of all 3 cells, which could be related to large electrolyte decomposition associated with formation of a thick or dense SEI layer. By contrast, the 2C and 1C cells show much less accumulative irreversible capacity, demonstrating much less overall electrolyte decomposition and suggests the formed SEI has shorter Na⁺ diffusion paths having one or more of the properties described above (thinner, less dense, more porous etc.).

When the cells were cycled at the same lower current density after formation, the cells from 2C formation shows the highest accumulative irreversible capacity for 6^{th}-10^{th} cycles, which could be due to ongoing SEI formation. Regardless, after 25 cycles, the accumulative irreversible capacity from 1/10C the formation test cell has the highest values up to 70 mAh/g, indicating the SEI formed at high current density formation and its nature has a profound impact on the long term cycling compared with the low current density formation test cell, and thus the formed subject cells lead to better capacity utilization.

### Example 7—NMR Studies

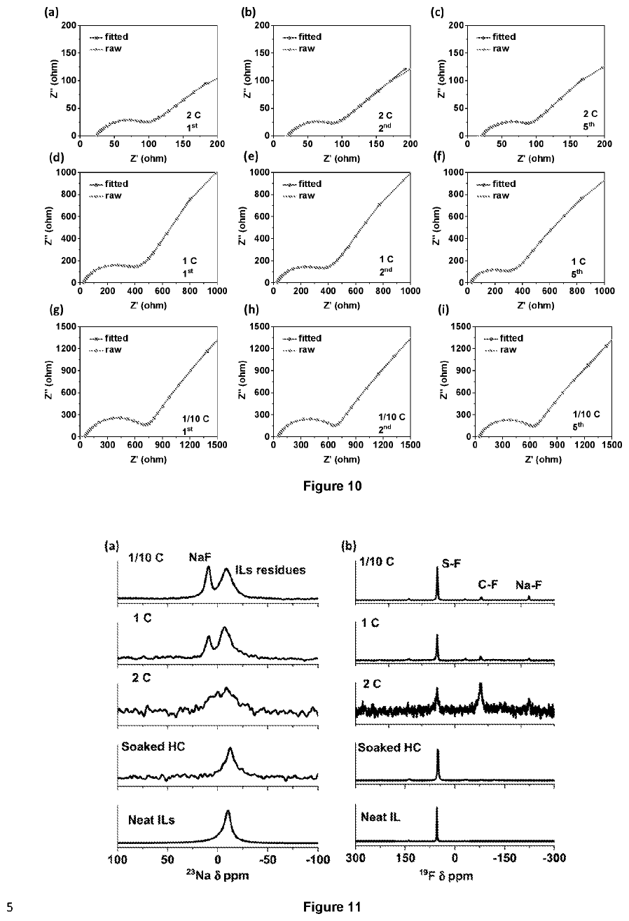

To further investigate the interfacial properties of the HC electrodes under different formation protocols, solid-state 23Na and 19F MAS nuclear magnetic resonance (NMR) measurements were conducted. All electrodes were cycled in the super concentrated ionic liquid electrolytes under various C-rates (namely 1/10 C, 1 C and 2 C). A control sample soaked in the electrolytes (denoted as Soaked HC) is also included. All of the spectra in FIG. 11a are normalized to the electrolyte residue signals for 23Na and in FIG. 11b by the electrolyte residue signal (S-F) for the 19F spectra. This is because it is difficult to quantitatively measure the sample amount due to the very small quantities involved, as well as the addition of the boron nitride filler material into the small sample rotor. In FIG. 11a, the IL residue signal at −8.9 ppm is observed for all the electrodes, indicating that the IL residues cannot be easily washed away by organic solvent. However, we did observe another peak at +9.2 ppm for the three formation electrodes, while the signal is not visible for the soaked HC. This peak is assigned to NaF according to the literature, which is from the electrolyte decomposition products. Interestingly, although we normalized the spectra with the ILs residues, we see that the S/N ratio is very low for the 2 C sample while 1/10 C has the highest value. This constitutes evidence of the lower amount of SEI material on the 2 C electrodes, agreeing well with the EIS and XPS results. The 19F MAS spectra was also tested for further exploration of the SEI composition. There are three fluorine peaks in FIG. 11b, attributed to S-F groups from electrolyte residue, C—F groups from the MAS rotor material (i.e., a background signal not arising from the sample), and the NaF peak from the electrolyte decomposition. The NaF peak again only shows up in the three formation electrodes, instead of the HC soaked one. Meanwhile, the S/N ratio for the 2 C cell is the lowest, consistent with the 23Na spectra.

### CONCLUSION

The inventors have developed an optimized formation protocol on hard carbon anodes for sodium-ion batteries when using a superconcentrated IL electrolyte. By adjusting the current densities within a fixed potential range, the total formation time can be shortened by a factor of 38× while still maintaining the electrochemical performance. The batteries under high C-rate (2 C, C=300 mAh/g) even outperform their counterparts at low C-rate formation when cycling at ½ C over a long-term testing. A comprehensive analysis of the SEI layer through three-electrode EIS, XPS and NMR techniques, demonstrates that a thinner and more ionically conductive SEI structure was developed by our optimized formation protocols. The interfacial resistance from the EIS test for the high rate formation cell also confirms the facilitated Na⁺ diffusion kinetics across the SEI layer, which is the result of the high ionically conductive SEI layer formation.

In conclusion, three formation protocols were investigated for NIB hard carbon anodes in superconcentrated ionic liquid electrolytes. In contrast to established methods for carbonate-based solvents [6,41], a high current density 2 C formation protocol resulted in the highest specific capacity during subsequent cycling at ½ C current density, along with the lowest EIS resistance, compared with 1 C and 1/10 C formation protocols. Variable cycling conditions (e.g., ⅕ C for long term cycling) were not influenced by the high C-rate treatment, demonstrating the necessity of applying high rate formation protocols for conditioning in these electrolytes. XPS and NMR analysis revealed a thinner SEI layer was formed after high C-rate formation, which can facilitate the Na⁺ charge transfer and diffusion across the electrolyte/electrode boundary. Minor but significant differences in SEI composition (absence of reduced S and N species after high rate formation) may also have contributed to the enhanced performance of the 2 C sample. The optimized formation protocol outperformed the traditional low-rate formation in sodium-ion batteries. Such a new formation protocol may have a big impact for industrial applications, enabling the use of alternative safe electrolyte materials such as ILs, by decreasing the formation time and manufacturing costs.

1. An electrochemical cell, comprising:
a super concentrated sodium salt containing ionic liquid electrolyte comprising at least one ionic liquid and at least one sodium salt, wherein the sodium salt concentration in the super concentrated sodium salt/ionic liquid electrolyte is 75% or greater of its saturation limit in the electrolyte;
a counter electrode or a positive electrode comprising an electrochemically oxidisable material that releases sodium ions from the material into the super concentrated electrolyte in the cell during a sodiation step or a charging step, and
a hard carbon working electrode or a negative electrode that absorbs sodium ions received at the hard carbon negative electrode from the super concentrated electrolyte as reduced sodium stored in the hard carbon during a sodiation step or a charging step, and wherein,
(a) the hard carbon negative electrode comprises a formed solid electrode interface (SEI) that is:
substantially free of low ordered/short range sulfur (S₈²⁻ to S²⁻) species;
and optionally
substantially free of atomic nitrogen species;
and/or
(b) the solid electrode interface (SEI)/hard carbon electrode has interfacial resistance associated with the SEI (Rᵢₙₜ) of less than 200 Ohms after a first formation cycle as determined by electrochemical impedance spectroscopy.

2. The electrochemical cell of claim 1, wherein the formed SEI is generated by reduction of the electrolyte on the hard carbon electrode by polarising a corresponding pristine cell for up to 5 formation cycles at a high constant current density ranging from ½ C to 5 C within a full voltage window for the cell.

3. The electrochemical cell of claim 1, wherein the formed SEI is generated by reduction of the electrolyte on the hard carbon electrode by polarising a corresponding pristine cell for up to 2 formation cycles at a constant current at a current density of 2 C within a full voltage window for the cell.

4. The electrochemical cell of any one of claim 1, wherein the SEI composition has one or more of
outer layers comprising more C-N species than the SEI of the formed test cell, as indicated by XPS testing and/or etching studies;
a composition comprising a ratio of C and O after 40 min etching which is 1 or greater which mirror pristine hard carbon after 40 minutes Ar⁺ cluster etching.

5. The electrochemical cell of any one of claim 1, wherein after completion of SEI formation cycling, during nominal C-rate cycling using a C-rate of ½ C or slower, the cell exhibits a Coulombic efficiency (CE) of 99.2% or greater.

6. The electrochemical cell of any one of claim 1, wherein the ionic liquid of the super concentrated electrolyte comprises a FSI⁻ anion, or a TFSI⁻ anion.

7. The electrochemical cell of claim 1, wherein the ionic liquid of the super concentrated electrolyte comprises pyrrolidinium cation.

8. The electrochemical cell of claim 1, wherein the electrolyte comprises Na[TFSI] and [C₃mpyr][TFSI], Na[TFSI] and [C₄C₃pyr][TFSI], Na[TFSI] and [C₃mpyr][FSI], Na[TFSI] and [C₄C₃mpyr][FSI], Na[FSI] and [C₃mpyr][TFSI], Na[FSI] and [C₄C₃mpyr][TFSI], Na[FSI] and [C₃mpyr][FSI], Na[FSI] and [C₄C₃mpyr][FSI], or combinations thereof.

9. The electrochemical cell of any one of claim 1, wherein the electrolyte is [C₃mpyr][FSI]ionic liquid or [C₃mpyr][TFSI] ionic liquid, with at least about 50 mol % NaFSI salt.

10. The electrochemical cell of claim 1, wherein the super concentrated electrolyte and the formed SEI are free of carbonate species.

11. The electrochemical cell of any one of claim 1, wherein the cell is in a full cell configuration and the counter electrode comprises, or is composed of, a material that can reversibly intercalate/deintercalated sodium ions within their atomic structure, absorb/desorb sodium ions by reversible oxidation/reduction reactions, or promote alloying/dealloying reactions with sodium ions.

12. The electrochemical cell of claim 1, wherein the counter electrode or positive electrode comprises, or is composed of, Na_{0.45}Ni_{0.22}Co_{0.11}Mn_{0.66}O₂, Na_{2/3}Fe_{2/3}Mn_{2/3} (O3), Na_{2/3}Fe_{2/3}Mn_{1/3}O₂ (P2), olivine-type NaFePO₄, NaₓFePO₄, silicates, or Nasicon type phases of general formula Na₂M₂ (XO₄)₃ where M=transition metal and X═P, S.

13. (canceled)

14. (canceled)

15. A cell formation method comprising the steps of:
providing a pristine cell based on sodium ion electrochemistry, the pristine cell comprising:
a counter electrode or a positive electrode comprising an electrochemically oxidisable material that releases sodium ions from the material into the super concentrated electrolyte in the cell during a sodiation step or a charging step,
a hard carbon working electrode or a hard carbon negative electrode that absorbs sodium ions received at the hard carbon negative electrode from the super concentrated electrolyte as reduced sodium stored in the hard carbon during a sodiation step or a charging step, and
a super concentrated sodium salt containing ionic liquid electrolyte comprising at least one ionic liquid and at least one sodium salt,
wherein sodium ion concentration in the super concentrated ionic liquid electrolyte is 75% or greater of its saturation limit in the electrolyte;
producing a formed subject cell by generating a formed SEI by reduction of the electrolyte on the hard carbon electrode by polarising the pristine cell for up to 5 formation cycles at a high constant current density ranging from ½ C to 5 C, within a full voltage window for the cell,
wherein,
(a) the hard carbon negative electrode comprises a formed solid electrode interface (SEI) is:
substantially free of low ordered/short range sulfur (S₈²⁻ to S²⁻) species;
and optionally
substantially free of atomic nitrogen species;
and/or
(b) the solid electrode interface (SEI)/hard carbon electrode has interfacial resistance associated with the SEI (Rᵢₙₜ) of 200 Ohms or less after a first formation cycle as determined by electrochemical impedance spectroscopy.

16. The method of claim 15, wherein cell polarisation occurs by galvanostatically charging and discharging the cell.

17. The method of claim 15, wherein the cell is in a half cell configuration or a full cell configuration.

18. The method of claim 15, wherein a nominal C-rate for the formed subject cell is ½ C or ⅕ C.

19. The method of claim 15, wherein the formed subject cell is further galvanostatically cycled at the nominal C-rate of ½ C or slower for up to 50 cycles, wherein during nominal C-rate cycling, the formed subject cell exhibits a Coulombic efficiency (CE) of 99.2% or greater.

20. The method of claim 15, the method further comprising recording charge-discharge cycle during each formation polarisation cycle whereby observation of one or more markers in the recorded corresponding charge-discharge cycle associated with substantially complete and stable SEI formation on the hard carbon electrode indicates complete formation, wherein the markers are selected from:
(a) Discharge-charge curve markers/features selected from
lack of significant electrolyte reduction slopes and/or observation of substantially static electrolyte reduction slopes in a recorded voltage-capacity cycle;
observation of unchanging features/stability in features in the recorded charge-discharge cycle;
absence of ‘low voltage’ features (e.g., below about 1.5V after initial cycles for the exemplified half cell) in the recorded charge-discharge cycle; and
observation that the cell's cut off discharge potential limit and resultant discharge capacity is reached without presence/appearance of curve features associated with sodium ion insertion into the negative active electrode, that is, with an absence of intercalation features (e.g. sodiation/lithiation);
(b) Electrochemical Impedance Spectroscopy (EIS) markers/features selected from
evidence of a low and/or stable EIS span in electrochemical impedance studies e.g., involving recorded Nyquist plot analysis;
evidence of formation of a low impedance SEI; and
evidence of a more highly ionically conductive SEI than that of a formed test cell; and
(c) Differential capacity analysis markers/features selected from
absence of electrolyte reduction/decomposition and/or electrolyte additive reduction/decomposition peaks in a recorded differential capacity curves (dQ/dV);
absence of a metal ion insertion peak indicates complete discharge occurs prior to metal ion insertion; and
presence of peaks for adsorption of Na*ions ad/chemisorption onto the active sites of the hard carbon material at the higher rates instead of Na⁺ insertion peak signal cut off before full charge capacity is reached for high rate cells.
